(19) United States
(12) Patent Application Publication
(10) Pub. No.: US 2026/0218416 A1
(43) Pub. Date: Jul. 30, 2026

(54) GALLIUM ARSENIDE SINGLE CRYSTAL SUBSTRATE AND METHOD OF PRODUCING SAME

(71) Applicant: Sumitomo Electric Industries, Ltd., Osaka (JP)

(72) Inventors: Fuminori MITSUHASHI, Osaka (JP); Masahiro ADACHI, Osaka (JP); Yoshihiro SAITO, Osaka (JP); Yojiro NAKAYAMA, Osaka (JP)

(73) Assignee: Sumitomo Electric Industries, Ltd., Osaka (JP)

(21) Appl. No.: 19/149,928

(22) PCT Filed: Apr. 17, 2023
(86) PCT No.: PCT/JP2023/015312

§ 371 Date: Jul. 22, 2025

(51) Int. Cl. C30B 29/42; C30B 29/66; C30B 33/02

(52) U.S. Cl. CPC C30B 29/42; C30B 29/66; C30B 33/02

(57) ABSTRACT

A gallium arsenide single crystal substrate has R1, R2, R3, R4, R5, and R6, each of which is a first integrated intensity ratio, the first integrated intensity ratio is obtained by determining a spectrum of a detection intensity of a 3d electron of arsenic with respect to a binding energy of a photoelectron emitted to outside of the gallium arsenide single crystal substrate based on X-ray photoelectron spectroscopy in which X-ray is applied to a center of the main surface under each of specific conditions, and a relation in which at least one of R2, R3, and R4 is the largest among R1, R2, R3, R4, R5, and R6 is satisfied.

### TECHNICAL FIELD

The present disclosure relates to a gallium arsenide single crystal substrate and a method of producing the same.

### BACKGROUND ART

Japanese Patent Laying-Open No. 06-045318 (PTL 1) proposes a gallium arsenide single crystal substrate (hereinafter, also referred to as a “GaAs single crystal substrate”) with which thermal cleaning, which is an operation of removing an oxide film, can be performed at a low temperature in a short time. Such a GaAs single crystal substrate can be realized in such a manner that an interface transition layer rich in As and having a thickness of 3 Å or less is artificially formed at a surface thereof. Japanese Patent Laying-Open No. 2008-300747 (PTL 2) proposes to provide a GaAs wafer, which is made clean by at least cleaning a surface of a GaAs single crystal substrate with heat to such an extent that impurity and oxide at its surface can be removed by the thermal cleaning.

### CITATION LIST

### Patent Literature

PTL 1: Japanese Patent Laying-Open No. 06-045318
PTL 2: Japanese Patent Laying-Open No. 2008-300747

### SUMMARY OF INVENTION

A gallium arsenide single crystal substrate according to the present disclosure is a gallium arsenide single crystal substrate having a main surface having a circular shape. The gallium arsenide single crystal substrate has R1, R2, R3, R4, R5, and R6, each of which is a first integrated intensity ratio. The first integrated intensity ratio is obtained by determining a spectrum of a detection intensity of a 3d electron of arsenic with respect to a binding energy of a photoelectron emitted to outside of the gallium arsenide single crystal substrate based on X-ray photoelectron spectroscopy in which X-ray is applied to a center of the main surface under each of below-described specific conditions. The first integrated intensity ratio is a ratio of an integrated intensity of an arsenic element present as diarsenic pentoxide to a sum of the integrated intensity of the arsenic element present as the diarsenic pentoxide, an integrated intensity of an arsenic element present as diarsenic trioxide, an integrated intensity of an arsenic element present as gallium arsenide, and an integrated intensity of an arsenic element present as a metal arsenic. The R1 is obtained by performing the X-ray photoelectron spectroscopy under a below-described condition 1. The R2 is obtained by performing the X-ray photoelectron spectroscopy under a below-described condition 2. The R3 is obtained by performing the X-ray photoelectron spectroscopy under a below-described condition 3. The R4 is obtained by performing the X-ray photoelectron spectroscopy under a below-described condition 4. The R5 is obtained by performing the X-ray photoelectron spectroscopy under a below-described condition 5. The R6 is obtained by performing the X-ray photoelectron spectroscopy under a below-described condition 6. A relation in which at least one of the R2, the R3, and the R4 is the largest among the R1, the R2, the R3, the R4, the R5, and the R6 is satisfied.
The condition 1: X-ray incident energy of 150 eV and photoelectron take-off angle of 30°.
The condition 2: X-ray incident energy of 150 eV and photoelectron take-off angle of 45°.
The condition 3: X-ray incident energy of 150 eV and photoelectron take-off angle of 85°.
The condition 4: X-ray incident energy of 600 eV and photoelectron take-off angle of 30°.
The condition 5: X-ray incident energy of 600 eV and photoelectron take-off angle of 45°.
The condition 6: X-ray incident energy of 600 eV and photoelectron take-off angle of 85°.

A method of producing a gallium arsenide single crystal substrate according to the present disclosure is a method of producing a gallium arsenide single crystal substrate having a main surface having a circular shape. The method includes: preparing a gallium arsenide single crystal substrate precursor having a surface having a circular shape; and obtaining the gallium arsenide single crystal substrate from the gallium arsenide single crystal substrate precursor. The obtaining includes forming the surface of the gallium arsenide single crystal substrate precursor into a polished surface by polishing the surface, forming the polished surface into an alkali-cleaned surface by cleaning the polished surface with an alkali cleaning liquid, forming the alkali-cleaned surface into a first acid-cleaned surface by cleaning the alkali-cleaned surface with an acid cleaning liquid including 0.3 ppm by mass or more and 1 mass % or less of a first acid, forming the first acid-cleaned surface into a second acid-cleaned surface by immersing the first acid-cleaned surface in more than 0.5 mass % and 1 mass % or less of a second acid for 1 minute or more, and forming the second acid-cleaned surface into the main surface by performing heat treatment onto the second acid-cleaned surface in an inert gas atmosphere under conditions of 100° C. or more and 200° C. or less and 1 minute or more and 30 minutes or less. The second acid includes at least one selected from a group consisting of hydrofluoric acid, hydrochloric acid, nitric acid, and nitrous acid.

### BRIEF DESCRIPTION OF DRAWINGS

FIG. 1 is an exemplary graph showing a relation between an analysis depth (horizontal axis) from a main surface of a gallium arsenide single crystal substrate according to the present embodiment and a ratio (vertical axis) of each of an integrated intensity of an arsenic element present as diarsenic pentoxide, an integrated intensity of an arsenic element present as diarsenic trioxide, and an integrated intensity of an arsenic element present as a metal arsenic to an integrated intensity of the whole of the arsenic elements.

FIG. 2 is an explanatory diagram schematically illustrating a configuration of an analysis system using the X-ray photoelectron spectroscopy.

FIG. 3 is a graph showing an exemplary As3d spectrum after background correction as obtained based on X-ray photoelectron spectroscopy in which X-ray is applied to the center of a main surface of a gallium arsenide single crystal substrate according to the present embodiment.

FIG. 4 is an explanatory diagram illustrating five measurement points set on a gallium arsenide single crystal substrate having a diameter of 75 mm or more and less than 150 mm in the present embodiment.

FIG. 5 is an explanatory diagram illustrating nine measurement points set on a gallium arsenide single crystal substrate having a diameter of 150 mm or more and 205 mm or less in the present embodiment.

FIG. 6 is a flowchart showing a method of producing the gallium arsenide single crystal substrate according to the present embodiment.

### DETAILED DESCRIPTION

### [Problem to be Solved by the Present Disclosure]

As one of methods of evaluating a mirror surface property (i.e., presence or absence of a level difference) of a surface of an epitaxial film, haze is used, and it has been known that an increase in value of the haze is correlated with a decrease in device property. The haze refers to an amount of scattered light scattered due to an irregularity of the surface and fine defect and foreign matter present at the surface when laser light is applied to the surface of the epitaxial film. The haze is expressed as a ratio of the amount of scattered light to an amount of laser light incident on the surface. The haze is expressed based on parts per million (ppm) as a unit. It is evaluated that as the value of the haze is smaller, the surface has a higher mirror surface property and the level difference is smaller. The level difference results from a stacking fault generated when an epitaxial film is grown on the GaAs single crystal substrate, for example. Since the stacking fault depends on the mirror surface property of the main surface of the GaAs single crystal substrate, it is required to realize a GaAs single crystal substrate having a main surface having a high mirror surface property so as to reduce the value of the haze.

The thermal cleaning described above has been expected as one of means for realizing such a GaAs single crystal substrate having the main surface having the high mirror surface property by removing an oxide film in the main surface. However, in some cases, it is required to further reduce the value of haze of the epitaxial film grown on the main surface, which has been formed into the mirror surface by the thermal cleaning, of the GaAs single crystal substrate such as the one in PTL 1.

In view of the above, it is an object of the present disclosure to provide: a gallium arsenide single crystal substrate to improve a device property by attaining formation of an epitaxial film having a reduced value of haze; and a method of producing the gallium arsenide single crystal substrate.

### Advantageous Effect of the Present Disclosure

According to the present disclosure, it is possible to provide: a gallium arsenide single crystal substrate to improve a device property by attaining formation of an epitaxial film having a reduced value of haze; and a method of producing the gallium arsenide single crystal substrate.

### Description of Embodiments

First, an overview of an embodiment of the present disclosure will be described. In order to solve the above-described problem, the present inventors have completed the present disclosure as a result of diligent study. That is, the present inventors have paid attention to obtaining a main surface having a high mirror surface property in a gallium arsenide single crystal substrate by performing a novel cleaning method onto a gallium arsenide single crystal substrate precursor that has a surface having a circular shape and that is cut out from a gallium arsenide single crystal. Specifically, in addition to conventional liquid phase treatment using both or either one of an acidic solution and an alkaline solution, acid treatment using a second acid and heat treatment were newly performed. As a result, it has been found that with the GaAs single crystal substrate obtained through the novel cleaning method, the oxide film can be effectively removed using the thermal cleaning by suppressing progress of oxidation of the oxide film with passage of time. In this way, the GaAs single crystal substrate having the main surface having the high mirror surface property can be obtained to arrive at the GaAs single crystal substrate on which an epitaxial film having a reduced value of haze can be formed, thus completing the present disclosure.

Next, embodiments of the present disclosure will be listed and described.

[1] A gallium arsenide single crystal substrate according to one embodiment of the present disclosure is a gallium arsenide single crystal substrate having a main surface having a circular shape. The gallium arsenide single crystal substrate has R1, R2, R3, R4, R5, and R6, each of which is a first integrated intensity ratio. The first integrated intensity ratio is obtained by determining a spectrum of a detection intensity of a 3d electron of arsenic with respect to a binding energy of a photoelectron emitted to outside of the gallium arsenide single crystal substrate based on X-ray photoelectron spectroscopy in which X-ray is applied to a center of the main surface under each of below-described specific conditions. The first integrated intensity ratio is a ratio of an integrated intensity of an arsenic element present as diarsenic pentoxide to a sum of the integrated intensity of the arsenic element present as the diarsenic pentoxide, an integrated intensity of an arsenic element present as diarsenic trioxide, an integrated intensity of an arsenic element present as gallium arsenide, and an integrated intensity of an arsenic element present as a metal arsenic. The R1 is obtained by performing the X-ray photoelectron spectroscopy under a below-described condition 1. The R2 is obtained by performing the X-ray photoelectron spectroscopy under a below-described condition 2. The R3 is obtained by performing the X-ray photoelectron spectroscopy under a below-described condition 3. The R4 is obtained by performing the X-ray photoelectron spectroscopy under a below-described condition 4. The R5 is obtained by performing the X-ray photoelectron spectroscopy under a below-described condition 5. The R6 is obtained by performing the X-ray photoelectron spectroscopy under a below-described condition 6. A relation in which at least one of the R2, the R3, and the R4 is the largest among the R1, the R2, the R3, the R4, the R5, and the R6 is satisfied.
The condition 1: X-ray incident energy of 150 eV and photoelectron take-off angle of 30°.
The condition 2: X-ray incident energy of 150 eV and photoelectron take-off angle of 45°.
The condition 3: X-ray incident energy of 150 eV and photoelectron take-off angle of 85°.
The condition 4: X-ray incident energy of 600 eV and photoelectron take-off angle of 30°.
The condition 5: X-ray incident energy of 600 eV and photoelectron take-off angle of 45°.
The condition 6: X-ray incident energy of 600 eV and photoelectron take-off angle of 85°.

The gallium arsenide single crystal substrate having such a feature can have a main surface having a high mirror surface property because an oxide film can be effectively removed using thermal cleaning, with the result that an epitaxial film having a reduced value of haze can be formed thereon.

[2] Each of the R1, the R2, the R3, the R4, the R5, and the R6 is preferably 0.05 or more and 0.55 or less. Thus, the oxide film can be more effectively removed using the thermal cleaning.

[3] The R6 is preferably 0.1 or more and less than 0.2. Thus, the oxide film can be more effectively removed using the thermal cleaning.

[4] The R1 is preferably 0.2 or more and less than 0.35. Thus, the oxide film can be more effectively removed using the thermal cleaning.

[5] The gallium arsenide single crystal substrate preferably has a diameter of 75 mm or more and 205 mm or less. Thus, the gallium arsenide single crystal substrate having the diameter of 75 mm or more and 205 mm or less can be provided with the main surface having the high mirror surface property, with the result that an epitaxial film having a reduced value of haze can be formed thereon.

[6] The gallium arsenide single crystal substrate preferably has the following feature. The gallium arsenide single crystal substrate has a diameter of 75 mm or more and less than 150 mm. The gallium arsenide single crystal substrate has RS1, RS2, RS3, RS4, RS5, and RS6, each of which is a second integrated intensity ratio. The gallium arsenide single crystal substrate has a standard deviation and an average value of each of the RS1, the RS2, the RS3, the RS4, the RS5, and the RS6. The standard deviation and the average value of each of the RS1, the RS2, the RS3, the RS4, the RS5, and the RS6 are obtained by determining a spectrum of a detection intensity of a 3d electron of the arsenic with respect to a binding energy of a photoelectron emitted to the outside of the gallium arsenide single crystal substrate based on X-ray photoelectron spectroscopy in which X-ray is applied to each of five measurement points on the main surface under a respective one of the condition 1, the condition 2, the condition 3, the condition 4, the condition 5, and the condition 6. The standard deviation and the average value of each of the RS1, the RS2, the RS3, the RS4, the RS5, and the RS6 are a standard deviation and an average value of the ratio of the integrated intensity of the arsenic element present as the diarsenic pentoxide to the sum of the integrated intensity of the arsenic element present as the diarsenic pentoxide, the integrated intensity of the arsenic element present as the diarsenic trioxide, the integrated intensity of the arsenic element present as the gallium arsenide, and the integrated intensity of the arsenic element present as the metal arsenic. A ratio of the standard deviation of the RS1 to the average value of the RS1 is 0.1 or less. A ratio of the standard deviation of the RS2 to the average value of the RS2 is 0.1 or less. A ratio of the standard deviation of the RS3 to the average value of the RS3 is 0.1 or less. A ratio of the standard deviation of the RS4 to the average value of the RS4 is 0.2 or less. A ratio of the standard deviation of the RS5 to the average value of the RS5 is 0.2 or less. A ratio of the standard deviation of the RS6 to the average value of the RS6 is 0.11 or less. When the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4) respectively. Units of the D and each of the X and the Y in the coordinates (X, Y) are mm. Thus, since the oxide film is effectively removed using the thermal cleaning in the gallium arsenide single crystal substrate having the diameter of 75 mm or more and less than 150 mm, it is possible to obtain a main surface having a high mirror surface property, with the result that an epitaxial film having a reduced value of haze can be formed thereon.

[7] The gallium arsenide single crystal substrate preferably has the following feature. The gallium arsenide single crystal substrate has a diameter of 150 mm or more and 205 mm or less. The gallium arsenide single crystal substrate has RT1, RT2, RT3, RT4, RT5, and RT6, each of which is a third integrated intensity ratio.

The gallium arsenide single crystal substrate has a standard deviation and an average value of each of the RT1, the RT2, the RT3, the RT4, the RT5, and the RT6. The standard deviation and the average value of each of the RT1, the RT2, the RT3, the RT4, the RT5, and the RT6 are obtained by determining a spectrum of a detection intensity of a 3d electron of the arsenic with respect to a binding energy of a photoelectron emitted to the outside of the gallium arsenide single crystal substrate based on X-ray photoelectron spectroscopy in which X-ray is applied to each of five measurement points on the main surface under a respective one of the condition 1, the condition 2, the condition 3, the condition 4, the condition 5, and the condition 6. The standard deviation and the average value of each of the RT1, the RT2, the RT3, the RT4, the RT5, and the RT6 are a standard deviation and an average value of the ratio of the integrated intensity of the arsenic element present as the diarsenic pentoxide to the sum of the integrated intensity of the arsenic element present as the diarsenic pentoxide, the integrated intensity of the arsenic element present as the diarsenic trioxide, the integrated intensity of the arsenic element present as the gallium arsenide, and the integrated intensity of the arsenic element present as the metal arsenic. A ratio of the standard deviation of the RT1 to the average value of the RT1 is 0.1 or less. A ratio of the standard deviation of the RT2 to the average value of the RT2 is 0.1 or less. A ratio of the standard deviation of the RT3 to the average value of the RT3 is 0.2 or less. A ratio of the standard deviation of the RT4 to the average value of the RT4 is 0.2 or less. A ratio of the standard deviation of the RT5 to the average value of the RT5 is 0.1 or less. A ratio of the standard deviation of the RT6 to the average value of the RT6 is 0.2 or less. When the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2-10, 0), (0, D/2-10), (−(D/2-10), 0), and (0, −(D/2-10)) respectively. Units of the D and each of the X and the Y in the coordinates (X, Y) are mm. Thus, by effectively removing the oxide film using the thermal cleaning on the gallium arsenide single crystal substrate having the diameter of 150 mm or more and 205 mm or less, the main surface having a high mirror surface property can be obtained, with the result that an epitaxial film having a reduced value of haze can be formed thereon.

[8] Preferably, the gallium arsenide single crystal substrate has an epitaxial film disposed on the main surface, a maximum value of haze of a surface of the epitaxial film is 350 ppm or less, and an average value of the haze of the surface of the epitaxial film is 2.5 ppm or less. Thus, it is possible to provide the gallium arsenide single crystal substrate having the main surface on which the epitaxial film having a reduced value of haze is formed.

[9] A method of producing a gallium arsenide single crystal substrate according to one embodiment of the present disclosure is a method of producing a gallium arsenide single crystal substrate having a main surface having a circular shape. The method includes: preparing a gallium arsenide single crystal substrate precursor having a surface having a circular shape; and obtaining the gallium arsenide single crystal substrate from the gallium arsenide single crystal substrate precursor. The obtaining includes forming the surface of the gallium arsenide single crystal substrate precursor into a polished surface by polishing the surface, forming the polished surface into an alkali-cleaned surface by cleaning the polished surface with an alkali cleaning liquid, forming the alkali-cleaned surface into a first acid-cleaned surface by cleaning the alkali-cleaned surface with an acid cleaning liquid including 0.3 ppm by mass or more and 1 mass % or less of a first acid, forming the first acid-cleaned surface into a second acid-cleaned surface by immersing the first acid-cleaned surface in more than 0.5 mass % and 1 mass % or less of a second acid for 1 minute or more, and forming the second acid-cleaned surface into the main surface by performing heat treatment onto the second acid-cleaned surface in an inert gas atmosphere under conditions of 100° C. or more and 200° C. or less and 1 minute or more and 30 minutes or less. The second acid includes at least one selected from a group consisting of hydrofluoric acid, hydrochloric acid, nitric acid, and nitrous acid. With the production method having such a feature, it is possible to obtain a gallium arsenide single crystal substrate having a main surface with an oxide film that can be effectively removed using the thermal cleaning.

[10] Preferably, the method include forming an epitaxial film on the main surface. Thus, an epitaxial film having a reduced value of haze can be formed on the main surface.

### Details of Embodiments

Hereinafter, one embodiment (hereinafter, also referred to as “the present embodiment”) according to the present disclosure will be described more in detail, but the present disclosure is not limited thereto. Although explanation will be made in the description below with reference to figures, the same or corresponding elements will be denoted by the same reference characters in the present specification and figures, and the same explanation therefor will not be described repeatedly. Moreover, in each of the figures, the scale of each component is appropriately adjusted in order to facilitate understanding, and the scale of each component shown in each of the figures does not necessarily coincide with the actual scale of the component.

In the present specification, the expression “A to B” represents a range of lower to upper limits (i.e., A or more and B or less), and when no unit is indicated for A and a unit is indicated only for B, the unit of A is the same as the unit of B. Moreover, when a compound or the like is expressed by a chemical formula in the present specification and an atomic ratio is not particularly limited, it is assumed that all the conventionally known atomic ratios are included, and the atomic ratio should not be necessarily limited only to one in the stoichiometric range.

In the present specification, a “main surface” of a gallium arsenide single crystal substrate means each of two circular surfaces of the substrate. When at least one of the two surfaces of the gallium arsenide single crystal substrate satisfies the scope of claims with regard to the present disclosure, the gallium arsenide single crystal substrate falls within the scope of the present invention. An epitaxial film may be disposed on the “main surface” of the gallium arsenide single crystal substrate. Moreover, in the present specification, the term “plane” used in the expression “in-plane” or “in the plane” means the “main surface”. Further, when it is described that the diameter of the gallium arsenide single crystal substrate is “75 mm”, it means that the diameter is about 75 mm (about 75 to 76.5 mm) or 3 inches. When it is described that the diameter is “100 mm”, it means that the diameter is about 100 mm (about 95 to 105 mm) or 4 inches. When it is described that the diameter is “150 mm”, it means that the diameter is about 150 mm (about 145 to 155 mm) or 6 inches. When it is described that the diameter is “200 mm”, it means that the diameter is about 200 mm (about 195 to 205 mm) or 8 inches. It should be noted that the diameter can be measured by using a conventionally known outer diameter measurement device such as a caliper.

Regarding crystallographic indications in the present specification, an individual orientation is represented by [ ], a group orientation is represented by < >, and an individual plane is represented by ( ) and a group plane is represented by { }. Moreover, a negative crystallographic index is normally expressed by putting “−” (bar) above a numeral, but is expressed by putting the negative sign before the numeral when stated in the present specification.

### [Gallium Arsenide Single Crystal Substrate]

A gallium arsenide single crystal substrate (GaAs single crystal substrate) according to the present embodiment is a GaAs single crystal substrate having a main surface having a circular shape. The GaAs single crystal substrate has R1, R2, R3, R4, R5, and R6, each of which is a first integrated intensity ratio. The first integrated intensity ratio is obtained by determining a spectrum of a detection intensity of a 3d electron of arsenic with respect to a binding energy of a photoelectron emitted to outside of the gallium arsenide single crystal substrate based on X-ray photoelectron spectroscopy in which X-ray is applied to a center of the main surface under each of below-described specific conditions. The first integrated intensity ratio is a ratio of an integrated intensity of an arsenic (As) element (hereinafter, also referred to as “As⁵⁺” for convenience) present as diarsenic pentoxide (As₂O₅) to a sum of the integrated intensity of the As element (As⁵⁺) present as the As₂O₅, an integrated intensity of an As element (hereinafter, also referred to as “As³⁺” for convenience) present as diarsenic trioxide (As₂O₃), an integrated intensity of an As element (hereinafter, also referred to as “Ga—As” for convenience) present as gallium arsenide (GaAs), and an integrated intensity of an As element (hereinafter, also referred to as “metal As” for convenience) present as a metal arsenic (metal As). R1 is obtained by performing the X-ray photoelectron spectroscopy under a below-described condition 1. R2 is obtained by performing the X-ray photoelectron spectroscopy under a below-described condition 2. R3 is obtained by performing the X-ray photoelectron spectroscopy under a below-described condition 3. R4 is obtained by performing the X-ray photoelectron spectroscopy under a below-described condition 4. R5 is obtained by performing the X-ray photoelectron spectroscopy under a below-described condition 5. R6 is obtained by performing the X-ray photoelectron spectroscopy under a below-described condition 6. A relation in which at least one of R2, R3, and R4 is the largest among R1, R2, R3, R4, R5, and R6 is satisfied.
Condition 1: X-ray incident energy of 150 eV and photoelectron take-off angle of 30°
Condition 2: X-ray incident energy of 150 eV and photoelectron take-off angle of 45°.
Condition 3: X-ray incident energy of 150 eV and photoelectron take-off angle of 85°.
Condition 4: X-ray incident energy of 600 eV and photoelectron take-off angle of 30°
Condition 5: X-ray incident energy of 600 eV and photoelectron take-off angle of 45°
Condition 6: X-ray incident energy of 600 eV and photoelectron take-off angle of 85°.

From the GaAs single crystal substrate having such a feature, an oxide film can be effectively removed using thermal cleaning, with the result that the GaAs single crystal substrate can have a main surface having a high mirror surface property.

Therefore, an epitaxial film having a reduced value of haze can be formed on the GaAs single crystal substrate.

### <Main Surface>

The GaAs single crystal substrate has the main surface having the circular shape as described above. In the present specification, the “circular shape” representing the shape of the main surface includes not only a geometric circular shape but also a shape when the main surface does not form the geometric circular shape due to formation of at least one of a notch, an orientation flat (hereinafter, also referred to as “OF”), and an index flat (hereinafter, also referred to as “IF”). That is, the “shape when the main surface does not form the geometric circular shape” means a shape when the length of a line segment extending from any point on the notch, OF, and IF to the center of the main surface becomes short among line segments extending from any point on the outer periphery of the main surface to the center of the main surface. In other words, in the present specification, the main surface is said to have the “circular shape” based on the shape before the notch, OF, and IF are formed. Therefore, the position of the center of the main surface and the size (length) of the diameter of the substrate are determined based on the circular shape before the notch, OF, IF, and the like are formed. It should be noted that the “shape when the main surface does not form the geometric circular shape” also includes a shape when the lengths of all the line segments extending from any point on the outer periphery of the main surface to the center of the main surface are not necessarily the same due to the shape of the GaAs single crystal before being cut out as the GaAs single crystal substrate. In this case, the center of the main surface refers to the position of the center of gravity, and the diameter of the substrate refers to the length of the longest line segment among the line segments each extending from one point on the outer periphery of the substrate to another point on the outer periphery of the substrate via the center of the main surface.

### <X-Ray Photoelectron Spectroscopy (XPS) Using Synchrotron Radiation>

During development of the GaAs single crystal substrate on which an epitaxial film having a reduced value of haze can be formed, the present inventors have paid attention to X-ray photoelectron spectroscopy (XPS) using synchrotron radiation, by which the state of the main surface of the GaAs single crystal substrate can be analyzed with high precision. Specifically, the XPS using synchrotron radiation has been performed so as to attempt to specify a cause of deterioration of the mirror surface property of the main surface of the GaAs single crystal substrate and eliminate the cause in order to arrive at the GaAs single crystal substrate on which an epitaxial film having a reduced value of haze can be formed. Here, the XPS refers to an analysis method in which X-ray is applied to a sample and kinetic energy distribution of photoelectrons emitted from the sample is measured so as to obtain knowledge about types, abundances, chemical bonding states, and the like of elements present in a surface of the sample.

In general, when the main surface of the GaAs single crystal substrate is measured by the XPS, the XPS is often performed using X-ray having energy fixed to around 1.487 keV. However, when the X-ray having incident energy fixed to around 1.487 keV is used and a photoelectron take-off angle is 30°, the knowledge about the state of the main surface of the GaAs single crystal substrate is obtained as a state of average in a region from the main surface to a depth of about 5 nm. This region corresponds to about 20 atomic layers when converted into atomic layers. For this reason, in the XPS, it becomes difficult to analyze the state of the main surface of the GaAs single crystal substrate with high precision. Further, when the X-ray having incident energy fixed to around 1.487 keV is used and the photoelectron take-off angle is deviated in the XPS so as to obtain knowledge about the state of the main surface of the GaAs single crystal substrate, a measurement error with respect to the angle becomes too large and a measurement error also becomes large due to a small ionization efficiency of the photoelectron intensity, with the result that it is also difficult to perform the analysis with high precision.

On the other hand, in the present disclosure, since the XPS is performed under conditions (hereinafter, also referred to as “specific conditions”) that the X-ray having an X-ray incident energy of 150 eV or 600 eV is used and the photoelectron take-off angle is set to 30°, 45°, or 85° as shown in the following conditions 1 to 6, the state of the main surface of the GaAs single crystal substrate can be analyzed.
Condition 1: X-ray incident energy of 150 eV and photoelectron take-off angle of 30°.
Condition 2: X-ray incident energy of 150 eV and photoelectron take-off angle of 45°.
Condition 3: X-ray incident energy of 150 eV and photoelectron take-off angle of 85°
Condition 4: X-ray incident energy of 600 eV and photoelectron take-off angle of 30°
Condition 5: X-ray incident energy of 600 eV and photoelectron take-off angle of 45°
Condition 6: X-ray incident energy of 600 eV and photoelectron take-off angle of 85°

When the X-ray incident energy is set to 150 eV and the photoelectron take-off angle is set to 30° (condition 1), the knowledge about the state of the main surface of the GaAs single crystal substrate can be obtained as a state of average in a region from the main surface to a depth of about 0.90 nm. When the X-ray incident energy is set to 150 eV and the photoelectron take-off angle is set to 45° (condition 2), the knowledge about the state of the main surface of the GaAs single crystal substrate can be obtained as a state of average in a region from the main surface to a depth of about 1.28 nm. When the X-ray incident energy is set to 150 eV and the photoelectron take-off angle is set to 85° (condition 3), the knowledge about the state of the main surface of the GaAs single crystal substrate can be obtained as a state of average in a region from the main surface to a depth of about 1.80 nm.

When the X-ray incident energy is set to 600 eV and the photoelectron take-off angle is set to 30° (condition 4), the knowledge about the state of the main surface of the GaAs single crystal substrate can be obtained as a state of average in a region from the main surface to a depth of about 2.25 nm. When the X-ray incident energy is set to 600 eV and the photoelectron take-off angle is set to 45° (condition 5), the knowledge about the state of the main surface of the GaAs single crystal substrate is obtained as a state of average in a region from the main surface to a depth of about 3.18 nm. When the X-ray incident energy is set to 600 eV and the photoelectron take-off angle is set to 85° (condition 6), the knowledge about the state of the main surface of the GaAs single crystal substrate can be obtained as a state of average in a region from the main surface to a depth of about 4.48 nm. That is, the region from the main surface of the GaAs single crystal substrate to the depth of about 5 nm (corresponding to about 20 atomic layers) can be analyzed in detail for about every one to three atomic layers. Thus, the state of the main surface can be analyzed more precisely than in the conventional art.

It has been known that an oxide film having a thickness of about 1 to 2 nm is formed in the main surface of the GaAs single crystal substrate after cleaned by a cleaning step. Therefore, attempts have been made to form an epitaxial film on the main surface after removing the oxide by thermal cleaning, so as to reduce a value of haze of a surface of the epitaxial film. However, a portion of the oxide film remains in the main surface even after the thermal cleaning, with the result that the value of the haze of the surface of the epitaxial film is large to some extent. To address this, the present inventors have paid attention to analyzing, in a detailed manner by the above-described XPS using synchrotron radiation, the vicinity of an interface (i.e., region at a depth of about 1 to 2 nm from the main surface of the GaAs single crystal substrate) between the oxide film occupying the top surface of the main surface of the GaAs single crystal substrate and a layer (hereinafter, also referred to as a “main layer” of the GaAs single crystal substrate) composed of gallium (Ga) and arsenic (As) and located directly below the oxide film. As a result, the present inventors have found that: when the vicinity of the interface has a composition richer in As₂O₅ than that of the other region of the oxide film in the GaAs single crystal substrate, the oxide film is effectively removed by the thermal cleaning. That is, the present inventors have conceived to appropriately control the composition of the oxide film in vicinity of the interface so as to obtain the main surface having the high mirror surface property. It should be noted that in the present specification, the “surface” of the oxide film refers to a surface of the oxide film opposite to the GaAs single crystal substrate side.

### <First Integrated Intensity Ratio>

The GaAs single crystal substrate according to the present embodiment has R1, R2, R3, R4, R5, and R6, each of which is the first integrated intensity ratio. The first integrated intensity ratio is obtained by determining the spectrum of the detection intensity of the 3d electron of the arsenic with respect to the binding energy of the photoelectron emitted to the outside of the gallium arsenide single crystal substrate based on the XPS in which the X-ray is applied to the center of the main surface under each of the above-described specific conditions (conditions 1 to 6). The first integrated intensity ratio is the ratio of the integrated intensity of the As element (As⁵⁺) present as the As₂O₅ to the sum of the integrated intensity of the As element (As⁵⁺) present as the As₂O₅, the integrated intensity of the As element (As³⁺) present as the As₂O₃, the integrated intensity of the As element (Ga—As) present as the GaAs, and the integrated intensity of the As element (metal As) present as the metal As. Moreover, R1 is obtained by performing the XPS under condition 1. R2 is obtained by performing the XPS under condition 2. R3 is obtained by performing the XPS under condition 3. R4 is obtained by performing the XPS under condition 4. R5 is obtained by performing the XPS under condition 5. R6 is obtained by performing the XPS under condition 6.

When the first integrated intensity ratio is represented by RF, the first integrated intensity ratio (RF) can be represented by the following mathematical formula.

$${R}_{F} = \frac{I ( {As}_{2} {O}_{5} )}{I ( {As}_{2} {O}_{5} ) + I ( {As}_{2} {O}_{3} ) + I ( GaAs ) + I ( As )} \qquad [ Math . 1 ]$$

In the GaAs single crystal substrate according to the present embodiment, a relation in which at least one of R2, R3, and R4 is the largest among R1, R2, R3, R4, R5, and R6 is satisfied. In particular, a relation in which R1 is smaller than each of R2 and R3 is preferably satisfied.

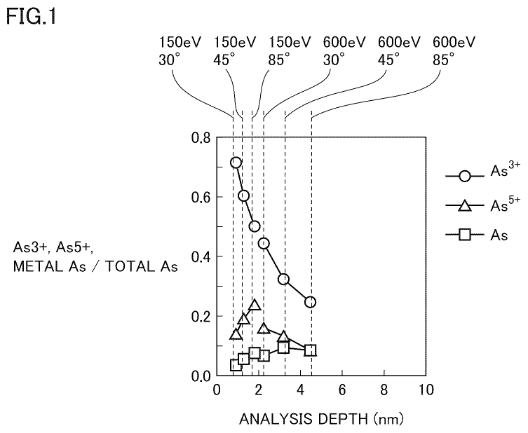

FIG. 1 is an exemplary graph showing a relation between an analysis depth (horizontal axis) from the main surface of the gallium arsenide single crystal substrate according to the present embodiment and a ratio (vertical axis) of each of the integrated intensity of the arsenic element present as the diarsenic pentoxide, the integrated intensity of the arsenic element present as the diarsenic trioxide, and the integrated intensity of the arsenic element present as the metal arsenic to the integrated intensity of the whole of the arsenic elements. Points indicated by triangles in FIG. 1 respectively correspond to R1, R2, R3, R4, R5, and R6, each of which is the above-described first integrated intensity ratio. According to the graph of FIG. 1, it is understood that R3, which is the first integrated intensity ratio obtained by performing the XPS under condition 3, is the largest among R1, R2, R3, R4, R5, and R6. Moreover, it is also understood that R1, which is the first integrated intensity ratio obtained by performing the XPS under condition 1, is smaller than each of R2 and R3.

Such a relation means that the composition of the oxide film in the vicinity of the interface between the oxide film located at a depth of about 1 to 2 nm from the main surface and the main layer is richer in As₂O₅ than that of the other region of the oxide film. In this case, it is estimated that since progress of oxidation is suppressed with respect to passage of time until the thermal cleaning is applied to the oxide film, the oxide film can be effectively removed by the thermal cleaning. Thus, when an epitaxial film is grown on the main surface of the GaAs single crystal substrate according to the present embodiment after the thermal cleaning, both maximum value and average value of haze of a surface of the epitaxial film can be smaller than those in the conventional art (for example, the maximum value of the haze of the surface of the epitaxial film can be 350 ppm or less, and the average value of the haze can be 2.5 ppm or less). In the present specification, the “surface” of the epitaxial film refers to a surface of the epitaxial film opposite to the GaAs single crystal substrate side.

On the other hand, when each of R1, R2, R3, R4, R5, and R6, each of which is the first integrated intensity ratio, is obtained by performing the XPS onto a conventional GaAs single crystal substrate, the conventional GaAs single crystal substrate does not satisfy the relation in which at least one of R2, R3, and R4 is the largest among R1, R2, R3, R4, R5, and R6 unlike the GaAs single crystal substrate according to the present embodiment. For example, in a GaAs single crystal substrate obtained by performing a liquid phase process using both or either one of a conventional acidic solution and an alkaline solution without performing the novel cleaning method described later, R1 is the largest among R1 to R6 and a portion of the oxide film may remain in the main surface even after the thermal cleaning. Therefore, when an epitaxial film is formed on the main surface of the GaAs single crystal substrate after the thermal cleaning, a level difference is caused in the surface, with the result that the maximum value and average value of the haze may become large. It should be noted that it can be said that R5 or R6 cannot be largest among R1 to R6 in reality because this indicates a GaAs single crystal substrate having a main surface in which no oxide film or a very thin oxide film is present.

As described above, the present inventors have first found that the haze of the surface of the epitaxial film formed on the main surface of the GaAs single crystal substrate depends on the amount of As₂O₅ in the vicinity of the interface (region at the depth of 1 to 2 nm from the main surface) between the oxide film and the main layer.

In the GaAs single crystal substrate, each of R1, R2, R3, R4, R5, and R6 is preferably 0.05 or more and 0.55 or less. When the content of the As₂O₅ in the oxide film is in the above-described range, the content of the As₂O₅ in the oxide film is sufficiently small, with the result that the As₂O₅ can be efficiently decomposed by the thermal cleaning. Each of R1, R2, R3, R4, R5, and R6 is more preferably 0.1 or more and 0.5 or less. It should be noted that a GaAs single crystal substrate in which each of R1, R2, R3, R4, R5, and R6 is less than 0.05 or is more than 0.55 is rare in reality.

Further, R6 is preferably 0.1 or more and less than 0.2. Thus, it is understood that the oxide film is sufficiently thin, with the result that the oxide film can be more effectively removed by using the thermal cleaning. R6 is more preferably 0.1 or more and 0.16 or less.

R1 is preferably 0.2 or more and less than 0.35. Thus, it is understood that the content of the As₂O₅ in the top surface of the oxide film is sufficiently small, with the result that the oxide film can be more effectively removed using the thermal cleaning. R1 is more preferably 0.2 or more and 0.33 or less.

### <Diameter>

The GaAs single crystal substrate preferably has a diameter of 75 mm or more and 205 mm or less. In other words, the diameter of the GaAs single crystal substrate is preferably 3 to 8 inches. Thus, in the GaAs single crystal substrate having the diameter of 75 mm or more and 205 mm or less, the main surface having the high mirror surface property can be obtained by effectively removing the oxide film using thermal cleaning. Here, regarding the diameter, even when the substrate has a shape that does not form a geometric circular shape due to influence of the OF, IF, or the like, the size (diameter) of the substrate is determined on such an assumption that the substrate has a circular shape before the formation of the OF, IF, or the like. The GaAs single crystal substrate preferably has a diameter of 100 mm or more and 205 mm or less, and also preferably has a diameter of 150 mm or more and 205 mm or less.

### <Method of Analyzing GaAs Single Crystal Substrate by X-Ray Photoelectron Spectroscopy (XPS) Using Synchrotron Radiation>

Hereinafter, the method of analyzing the GaAs single crystal substrate by the XPS using synchrotron radiation will be described more in detail.

### (Analysis System)

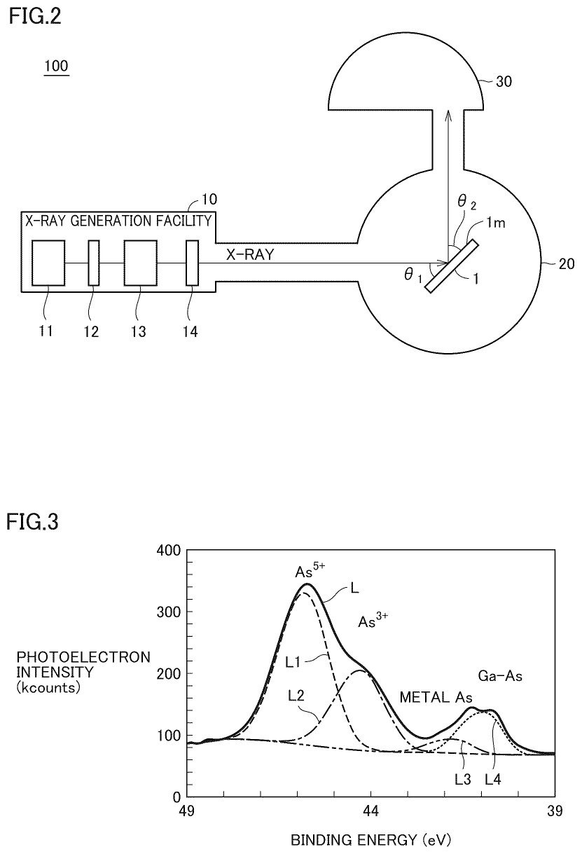

FIG. 2 is an explanatory diagram schematically illustrating a configuration of an analysis system using the X-ray photoelectron spectroscopy. As shown in FIG. 2, an analysis system 100 includes an X-ray generation facility 10, a vacuum container 20, and an electron spectrometer 30. X-ray generation facility 10, vacuum container 20, and electron spectrometer 30 are coupled together in this order. An internal space of each of X-ray generation facility 10, vacuum container 20, and electron spectrometer 30 is maintained in ultrahigh vacuum. A pressure in the internal space of each of X-ray generation facility 10, vacuum container 20, and electron spectrometer 30 is, for example, 4×10⁻⁷ Pa.

X-ray generation facility 10 generates X-ray, which is referred to as synchrotron radiation. As X-ray generation facility 10, for example, the beamline “BL17” in SAGA Light Source can be used.

X-ray generation facility 10 can generate X-ray having any energy in a range of 50 to 2000 eV in the “BL17” so as to apply the X-ray to GaAs single crystal substrate 1 placed in vacuum container 20. X-ray generation facility 10 illustrated in FIG. 2 has an X-ray source 11, slits 12, 14, and a grating 13. Slits 12, 14 are disposed on the upstream side and the downstream side with respect to grating (spectrometer) 13, respectively. Each of slits 12, 14 is, for example, a four-quadrant slit.

By bending a traveling direction of high-energy electron using a magnetic field generated by a bending electromagnet in a circular accelerator, X-ray source 11 outputs synchrotron radiation (X-ray) emitted in a direction along a line tangential to the traveling direction.

The X-ray emitted from X-ray source 11 has high luminance. Specifically, the number of photons of the X-ray emitted from X-ray source 11 per second is 109 photons/s. However, the luminance (intensity) of the X-ray emitted from X-ray source 11 is attenuated with passage of time. For example, the luminance of the X-ray emitted 11 hours after activation of X-ray source 11 is ⅓ of the luminance of the X-ray emitted immediately after the activation thereof.

The X-ray emitted from X-ray source 11 is collimated by a collimating mirror (not shown) or the like. Slit 12 allows a part of the collimated X-ray to pass therethrough. The X-ray having passed through slit 12 is monochromatized by grating 13. Slit 14 limits the breadth of the monochromatized X-ray.

The energy of the X-ray emitted from X-ray generation facility 10 is determined by the slit widths of slits 12, 14 and the line density of grating 13. For example, the X-ray of 150 eV or 600 eV can be emitted from X-ray generation facility 10 by adjusting an emission angle in the grating using grating 13 in which the slit width of each of slits 12, 14 is 30 μm and the line density at the center is 400 1/mm.

When the X-ray from X-ray generation facility 10 is applied to GaAs single crystal substrate 1 placed in vacuum container 20, photoelectrons are emitted from GaAs single crystal substrate 1.

Electron spectrometer 30 measures a kinetic energy distribution of the photoelectrons emitted from GaAs single crystal substrate 1. Electron spectrometer 30 has a hemispherical analyzer and a detector. The hemispherical analyzer divides the photoelectrons. The detector counts the number of photoelectrons of each energy.

An angle θ₁ formed by the traveling direction of the X-ray incident on GaAs single crystal substrate 1 from X-ray generation facility 10 and main surface 1m of GaAs single crystal substrate 1 is variable. Further, an angle (hereinafter, referred to as “take-off angle θ₂”) formed by the traveling direction of the photoelectron captured by electron spectrometer 30 among the photoelectrons emitted from GaAs single crystal substrate 1 and main surface 1m of GaAs single crystal substrate 1 is also variable. In the present embodiment, take-off angle θ₂ is set to 30°, 45°, or 85°. Angle θ₁ is not particularly limited, but is set to, for example, 85°.

As electron spectrometer 30, for example, a high-resolution XPS analyzer “R3000” provided by Scienta Omicron can be used.

(Depth from Main Surface for Analysis)

Part of the photoelectrons emitted to the outside of GaAs single crystal substrate 1 in response to the application of the X-ray lose its energy due to inelastic scattering. Therefore, only part of the photoelectrons generated in GaAs single crystal substrate 1 exit into the vacuum while maintaining the energy as large as that when generated, and reaches electron spectrometer 30. The photoelectrons to exit from the surface are generated at a depth corresponding to a depth about three times as large as the inelastic mean free path (IMFP) of the photoelectrons. Therefore, depth d (nm) from the main surface of the GaAs single crystal substrate for analysis is expressed by the following mathematical formula. In the following mathematical formula, λ (nm) represents the IMFP value, and θ₂ represents the take-off angle.

$$d = 3 λ sin {θ}_{2} \qquad [ Math . 2 ]$$

Further, as indicated in “‘Method of Estimating Inelastic Mean Free Path of Electrons by Tpp-2M Formula′, Journal of Surface Analysis, Vol. 1, No. 2, 1995”, λ (Å) is represented by the following mathematical formulas.

$$λ = \frac{E}{{E}_{p}^{2} [ β ln ( γ E ) - C / E + D / {E}^{2} ]} \qquad [ Math . 3 ]$$

$${E}_{p} = 28.8 {( \frac{{N}_{v} ρ}{{A}_{w}} )}^{1 / 2}$$

$$β = - 0.1 + \frac{0.944}{{( {E}_{p}^{2} + {E}_{g}^{2} )}^{\frac{1}{2}}} + 0.069 {ρ}^{0.1}$$

$$γ = 0. 191 {ρ}^{- 0.50}$$

$$C = 1.9 7 - 0 \text{.94} U$$

$$D = 53. 4 - 20.8 U$$

$$U = \frac{{N}_{v} ρ}{{A}_{w}} = \frac{{E}_{p}^{2}}{829.4}$$

In each of the above mathematical formulas, Aw represents atomic weight or molecular weight, Nᵥ represents the number of valence electrons per atom or molecule, Eₚ represents plasmon energy (eV) of free electron, p represents density (g/cm³), and E_{g} represents band gap energy (eV). E represents kinetic energy (eV) of the photoelectrons, and is calculated from the energy (eV) of the applied X-ray and the binding energy (eV) between the electron and the atomic nucleus.

Depth d (nm) from the main surface of the GaAs single crystal substrate for analysis can be determined by using each of the above mathematical formulas. That is, depth d (nm) from the main surface of the GaAs single crystal substrate is calculated by using each of the above mathematical formulas, various parameter values for the 3d electrons of the As element in the As₂O₅ and the As₂O₃, and the X-ray energy (150 eV or 600 eV). Depth d (nm) is as follows.

When the X-ray incident energy is 150 eV and the photoelectron take-off angle is 30° (condition 1), depth d is about 0.90 nm. When the X-ray incident energy is 150 eV and the photoelectron take-off angle is 45° (condition 2), depth d is about 1.28 nm. When the X-ray incident energy is 150 eV and the photoelectron take-off angle is 85° (condition 3), depth d is about 1.80 nm. When the X-ray incident energy is 600 eV and the photoelectron take-off angle is 30° (condition 4), depth d is about 2.25 nm. When the X-ray incident energy is 600 eV and the photoelectron take-off angle is 45° (condition 5), depth d is about 3.18 nm. When the X-ray incident energy is 600 eV and the photoelectron take-off angle is 85° (condition 6), depth d is about 4.48 nm.

### (Method of Calculating First Integrated Intensity Ratio (R1, R2, R3, R4, R5, and R6))

Hereinafter, a method of calculating the first integrated intensity ratio (R1, R2, R3, R4, R5, and R6) in the main surface based on the above-described XPS will be described. In the present embodiment, first, the XPS is performed onto the center of the main surface of the GaAs single crystal substrate using X-ray having an energy of 150 eV or 600 eV. Thus, the kinetic energy distribution of the photoelectrons emitted from the GaAs single crystal substrate is obtained.

Kinetic energy E of the photoelectrons emitted from the GaAs single crystal substrate is expressed by the following mathematical formula using energy hv (eV) of the applied X-ray, binding energy EB (eV) of electrons in the GaAs single crystal substrate, and a work function q (eV).

$$E = hv - {E}_{B} - φ .$$

From the kinetic energy distribution of the photoelectrons emitted from the GaAs single crystal substrate, a spectrum indicating the binding energy distribution of the electrons is generated using the above mathematical formula. Here, in the present embodiment, an As3d spectrum indicating the binding energy distribution of the electrons is generated based on the kinetic energy distribution of the photoelectrons emitted from the position at depth d (nm) from the main surface of the GaAs single crystal substrate. In the present specification, the “As3d spectrum” refers to a spectrum representing a detection intensity of each photoelectron emitted from the 3d orbital of the As element (the As₂O₅, the As₂O₃, the metal As, and the As included in the GaAs).

In particular, in the analysis according to the XPS, from the viewpoint of precise measurement, the As3d spectrum is obtained by performing narrow scanning in a predetermined range of binding energy. Specifically, by performing narrow scanning in a range of binding energy of 39 to 49 eV, the As3d spectrum can be represented in a graph with the horizontal axis representing the range and the vertical axis representing the detection intensity.

The narrow scanning is performed under conditions that an energy interval is 0.05 eV, an integration time at each energy value is 100 ms, and the number of times of integrations is one or more. Further, an energy resolution E/AE is 3480.

FIG. 3 is a graph showing an exemplary As3d spectrum after background correction as obtained based on the X-ray photoelectron spectroscopy in which X-ray is applied to the center of the main surface of the gallium arsenide single crystal substrate according to the present embodiment. As shown in FIG. 3, in As3d spectrum L, the As element present as the GaAs (i.e., the As element bonded to Ga: Ga—As), the As element (As⁵⁺) present as the As₂O₅, the As element (As³⁺) present as As₂O₃, and the As element (metal As) present as the metal As appear. The metal As is generated from the oxide film and the main layer due to a reaction of 2GaAs+As₂O₃→Ga₂O₃+4As.

Here, when obtaining As3d spectrum L, the background correction is performed by using the Shirley method (reference document: Kazuhiro Yoshihara: Journal of the Vacuum Society of Japan, 2013, Vol. 56, No. 6, p. 243 to 247). Thus, a difference between the As3d spectrum obtained based on the actual measurement and the background can be determined as As3d spectrum L after the background correction.

Further, when obtaining As3d spectrum L, the peak of the detection intensity of the As⁵⁺ is fixed at a position corresponding to a binding energy of 45.57 eV, and the peak position of the detection intensity of the As³⁺ is fixed at a position corresponding to a binding energy of 44.07 eV. Further, the peak of the detection intensity of the metal As is set at a position corresponding to a binding energy of about 41.62 to 42.12 eV so as to have a width, and the peak of the detection intensity of the Ga—As is set at a position corresponding to a binding energy of about 40.77 to 41.27 eV so as to have a width. This is due to the following reason: when the X-ray photoelectron spectroscopy is performed onto the GaAs single crystal, charge shift may occur to cause As3d spectrum L to be shifted to the high energy side by about 1 eV at maximum. Moreover, since each peak of the metal As and the Ga—As is affected by the main layer composed of GaAs and it becomes difficult to fix the peak to one value, the peak position is set to have a width of 0.5 eV as described above.

Next, As3d spectrum L after the background correction as obtained in the manner described above is expressed by separation of As3d spectrum L into the following four Gaussian functions Y1, Y2, Y3 and Y4 (hereinafter, this operation is also referred to as “peak separation”). In this way, the four spectra of the As element (Ga—As) present as the GaAs, the As element (As⁵⁺) present as the As₂O₅, the As element (As³⁺) present as the As₂O₃, and the As element (metal As) present as the metal As can be obtained by the peak separation in the range of binding energy of 39 to 49 eV.

$$Y 1 = a {1}^{*} exp \{ ( - {( X - b 1 )}^{2} ) / c {1}^{2} \}$$

$$Y 2 = a {2}^{*} exp \{ ( - {( X - b 2 )}^{2} ) / c {2}^{2} \}$$

$$Y 3 = a {3}^{*} exp \{ ( - {( X - b 3 )}^{2} ) / c {3}^{2} \}$$

$$Y 4 = a {4}^{*} exp \{ ( - {( X - b 4 )}^{2} ) / c {4}^{2} \}$$

Among the four Gaussian functions, Y1 represents the spectrum of the As⁵⁺, Y2 represents the spectrum of the As³⁺, Y3 represents the spectrum of the metal As, and Y4 represents the spectrum of the Ga—As. The unit of each of Gaussian functions Y1, Y2, Y3 and Y4 is dimensionless, the unit of each of X, b1, b2, b3, b4, c1, c2, c3 and c4 in Gaussian functions Y1, Y2, Y3 and Y4 is eV, and the unit of each of a1, a2, a3 and a4 is dimensionless.

Gaussian functions Y1 to Y4 are determined by optimizing each of the variables (a1, a2, a3, a4, b1, b2, b3, b4, c1, c2, c3, c4) such that the square ([actual measurement —ΣGi]²) of a difference from the actual measurement becomes minimum, under premise that the i-th component of the As3d is expressed by Gaussian function Gi=Ai*exp{(−(E−E1)²)/Wi²}. The values of binding energy at the peaks of the detection intensities of the As⁵⁺, the As³⁺, the metal As, and the Ga—As described above are substituted to b1 to b4, respectively.

That is, each of the variables (a1, a2, a3, a4, b1, b2, b3, b4, c1, c2, c3, c4) is as follows.

Each of a1, a2, a3, and a4 is a real number of 0 or more.

$$b 1 = 45.57 eV$$

$$b 2 = 44.07 eV$$

$$41.62 eV \underline{<} b 3 \leq 42.12 eV$$

$$40.77 eV \underline{<} b 4 \leq 41.27 eV$$

$$0.2 eV \leq c 1 \leq 0.95 eV$$

$$0.2 eV \leq c 2 \leq 0.95 eV$$

$$0.2 eV \leq c 3 \leq 0.95 eV$$

$$0.2 eV \leq c 4 \leq 1.2 eV .$$

Thus, Gaussian functions Y1, Y2, Y3, and Y4 can be respectively represented as an As⁵⁺ spectrum L1, an As³⁺ spectrum L2, a metal As spectrum L3, and an Ga—As spectrum L4, which are obtained through the peak separation from As3d spectrum L of FIG. 3, for example.

It should be noted that in order to fix the peak positions of Gaussian functions Y1, Y2, Y3 and Y4, the following correction can be performed. First, a probability of generation of photoelectrons by X-ray, which is called photoionization efficiency (n), is variable depending on element, X-ray energy, and the like, and therefore data published in the following Web site is used as the value of n. Specifically, the photoionization efficiency (η) of the X-ray having an incident energy of 150 eV is 6.63, and the photoionization efficiency (η) of the X-ray having an incident energy of 600 eV is 0.42.

https://vuo.elettra.eu/services/elements/WebElements.html (see data for J. J. Yeh, Atomic Calculation of Photoionization Cross-Sections and Asymmetry Parameters, Gordon and Breach Science Publishers, Langhorne, PE (USA), 1993 and J. J. Yeh and I. Lindau, Atomic Data and Nuclear Data Tables, 32, 1-155 (1985)).

Moreover, since the intensity of the applied X-ray used in the synchrotron radiation facility is attenuated with passage of time, an attenuation ratio of Au4f photoelectron intensity is determined by measuring a gold (Au) standard sample at regular time intervals, and the dose of the applied X-ray is corrected based on the ratio.

For example, in FIG. 3, an area between Gaussian function Y1 (As⁵⁺ spectrum L1) and the horizontal axis (X axis) corresponds to the number of photoelectrons emitted from the 3d orbital of the As⁵⁺ and therefore means the integrated intensity of the As5+. An area found as an area between Y2 (As³⁺ spectrum L2) and the horizontal axis (X axis) corresponds to the number of photoelectrons emitted from the 3d orbital of the As³⁺ and therefore means the integrated intensity of the As³⁺. An area between Y3 (metal As spectrum L3) and the horizontal axis (X axis) corresponds to the number of photoelectrons emitted from the 3d orbital of the As and therefore means the integrated intensity of the metal As. An area between Y4 (Ga—As spectrum L4) and the horizontal axis (X axis) corresponds to the number of photoelectrons emitted from the 3d orbital of the Ga—As, and therefore means the integrated intensity of the Ga—As. Therefore, the ratio of the integrated intensity of the As⁵⁺ to the sum of the integrated intensity of the As⁵⁺, the integrated intensity of the As³⁺, the integrated intensity of the Ga—As, and the integrated intensity of the metal As can be obtained based on the areas obtained from the above-described Gaussian functions Y1, Y2, Y3, and Y4 and the horizontal axis, thereby determining the first integrated intensity ratio. It should be noted that each of R1, R2, R3, R4, R5, and R6, each of which is the first integrated intensity ratio, is determined when the XPS is performed under a respective one of conditions 1 to 6 as described above.

### <Uniformity of Main Surface of GaAs Single Crystal Substrate>

The property of the GaAs single crystal substrate according to the present embodiment is preferably uniform in the plane of the main surface. That is, the GaAs single crystal substrate according to the present embodiment is preferably such that an epitaxial film having a reduced value of haze can be formed thereon regardless of an in-plane position in the main surface. As specific implementations of such a preferable GaAs single crystal substrate, the following implementations (a first implementation and a second implementation) can be exemplified.

### (First Implementation)

The GaAs single crystal substrate according to the first implementation has the diameter of 75 mm or more and less than 150 mm. The GaAs single crystal substrate preferably has a diameter of 75 mm or more and 105 mm or less. The GaAs single crystal substrate has RS1, RS2, RS3, RS4, RS5, and RS6, each of which is a second integrated intensity ratio. The GaAs single crystal substrate has a standard deviation and an average value of each of RS1, RS2, RS3, RS4, RS5, and RS6. The standard deviation and the average value of each of RS1, RS2, RS3, RS4, RS5, and RS6 are obtained by determining a spectrum of a detection intensity of a 3d electron of the arsenic with respect to a binding energy of a photoelectron emitted to the outside of the gallium arsenide single crystal substrate based on X-ray photoelectron spectroscopy in which X-ray is applied to each of five measurement points on the main surface under a respective one of condition 1, condition 2, condition 3, condition 4, condition 5, and condition 6. The standard deviation and the average value of each of RS1, RS2, RS3, RS4, RS5, and RS6 are a standard deviation and an average value of the ratio of the integrated intensity of the As element present as the As₂O₅ to the sum of the integrated intensity of the As element present as the As₂O₅, the integrated intensity of the As element present as the As₂O₃, the integrated intensity of the As element present as the GaAs, and the integrated intensity of the As element present as the metal As.

A ratio of the standard deviation of RS1 to the average value of RS1 is 0.1 or less. A ratio of the standard deviation of RS2 to the average value of RS2 is 0.1 or less. A ratio of the standard deviation of RS3 to the average value of RS3 is 0.1 or less. A ratio of the standard deviation of RS4 to the average value of RS4 is 0.2 or less. A ratio of the standard deviation of RS5 to the average value of RS5 is 0.2 or less. A ratio of the standard deviation of RS6 to the average value of RS6 is 0.11 or less.

When the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4) respectively. Units of the D and each of the X and the Y in the coordinates (X, Y) are mm. Thus, since the oxide film is effectively removed using the thermal cleaning in the gallium arsenide single crystal substrate having the diameter of 75 mm or more and less than 150 mm, it is possible to obtain a main surface having a high mirror surface property, with the result that an epitaxial film having a reduced value of haze can be formed thereon.

In particular, the GaAs single crystal substrate according to the first implementation more preferably satisfies the following relation. The ratio of the standard deviation of RS1 to the average value of RS1 is more preferably 0.055 or less. The ratio of the standard deviation of RS2 to the average value of RS2 is more preferably 0.093 or less. The ratio of the standard deviation of RS3 to the average value of RS3 is more preferably 0.05 or less. The ratio of the standard deviation of RS4 to the average value of RS4 is 0.111 or less. The ratio of the standard deviation of RS5 to the average value of RS5 is more preferably 0.113 or less. The ratio of the standard deviation of RS6 to the average value of RS6 is more preferably 0.102 or less. For each of RS1, RS2, RS3, RS4, RS5, and RS6, the lower limit of the ratio of the standard deviation to the average value is 0, which is an ideal value. For example, for each of RS1, RS2, RS3, RS4, RS5, and RS6, the ratio of the standard deviation to the average value may be 0.026 or more.

### (Second Implementation)

Further, a GaAs single crystal substrate according to the second implementation has a diameter of 150 mm or more and 205 mm or less. The GaAs single crystal substrate has RT1, RT2, RT3, RT4, RT5, and RT6, each of which is a third integrated intensity ratio. The GaAs single crystal substrate has a standard deviation and an average value of each of RT1, RT2, RT3, RT4, RT5, and RT6. The standard deviation and the average value of each of RT1, RT2, RT3, RT4, RT5, and RT6 are obtained by determining a spectrum of a detection intensity of a 3d electron of the arsenic with respect to a binding energy of a photoelectron emitted to the outside of the GaAs single crystal substrate based on X-ray photoelectron spectroscopy in which X-ray is applied to each of five measurement points on the main surface under a respective one of condition 1, condition 2, condition 3, condition 4, condition 5, and condition 6. The standard deviation and the average value of each of RT1, RT2, RT3, RT4, RT5, and RT6 are a standard deviation and an average value of the ratio of the integrated intensity of the As element present as the As₂O₅ to the sum of the integrated intensity of the As element present as the As₂O₅, the integrated intensity of the As element present as the As₂O₃, the integrated intensity of the As element present as the GaAs, and the integrated intensity of the As element present as the metal As.

A ratio of the standard deviation of RT1 to the average value of RT1 is 0.1 or less. A ratio of the standard deviation of RT2 to the average value of RT2 is 0.1 or less. A ratio of the standard deviation of RT3 to the average value of RT3 is 0.2 or less. A ratio of the standard deviation of RT4 to the average value of RT4 is 0.2 or less. A ratio of the standard deviation of RT5 to the average value of RT5 is 0.1 or less. A ratio of the standard deviation of RT6 to the average value of RT6 is 0.2 or less.

When the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2-10, 0), (0, D/2-10), (−(D/2-10), 0), and (0, −(D/2-10)) respectively. Units of the D and each of the X and the Y in the coordinates (X, Y) are mm. Thus, by effectively removing the oxide film using the thermal cleaning on the GaAs single crystal substrate having the diameter of 150 mm or more and 205 mm or less, the main surface having a high mirror surface property can be obtained, with the result that an epitaxial film having a reduced value of haze can be formed thereon.

In particular, the GaAs single crystal substrate according to the second implementation more preferably satisfies the following relation. The ratio of the standard deviation of RT1 to the average value of RT1 is more preferably 0.071 or less. The ratio of the standard deviation of RT2 to the average value of RT2 is more preferably 0.07 or less. The ratio of the standard deviation of RT3 to the average value of RT3 is more preferably 0.11 or less. The ratio of the standard deviation of RT4 to the average value of RT4 is more preferably 0.12 or less. The ratio of the standard deviation of RT5 to the average value of RT5 is more preferably 0.092 or less. The ratio of the standard deviation of RT6 to the average value of RT6 is more preferably 0.11 or less. For each of RT1, RT2, RT3, RT4, RT5, and RT6, the lower limit of the ratio of the standard deviation to the average value is 0, which is an ideal value. For example, for each of RT1, RT2, RT3, RT4, RT5, and RT6, the ratio of the standard deviation to the average value may be 0.039 or more.

In each of the first implementation and the second implementation described above, since conditions 1, 2, 3, 4, 5, and 6 that are conditions for performing the XPS respectively correspond to the above-described conditions 1, 2, 3, 4, 5, and 6 that are conditions for the XPS performed to determine the first integrated intensity ratio, the same explanation will not be described repeatedly. Further, a specific analysis method for determining each of the second integrated intensity ratio and the third integrated intensity ratio is also the same as the method described in the section

<Method of Analyzing GaAs Single Crystal Substrate by X-Ray Photoelectron Spectroscopy (XPS) using Synchrotron Radiation>, and therefore the same explanation will not be described repeatedly.

### (Five Measurement Points and Nine Measurement Points)

The GaAs single crystal substrate according to the first implementation has the diameter of 75 mm or more and less than 150 mm. In this case, on the main surface of the GaAs single crystal substrate according to the first implementation, the five measurement points are set as follows. That is, in order to evaluate the effect of reducing the haze value of the epitaxial film due to the uniform in-plane distribution of the second integrated intensity ratio, it is appropriate to set the five measurement points such that distances therebetween become as large as possible, determine the second integrated intensity ratio at each of the five measurement points, and evaluate a variation thereof. Therefore, on the main surface of the GaAs single crystal substrate, five circular measurement targets each having a diameter of 20 mm are first set such that distances therebetween become as large as possible. Next, the center of each measurement target is set as the measurement point. Then, X-ray is applied to the measurement point.

When the two axes, which each pass through the center of the main surface, are each located on the main surface, and are orthogonal to each other, are defined as the X axis and the Y axis, the coordinates (X, Y) of the first measurement point among the five measurement points on the X axis and the Y axis are set to (0, 0). It should be noted that each of the X axis and the Y axis is set such that a notch formed in the GaAs single crystal substrate is located in the third quadrant of the XY coordinate plane and a general angle of a half line passing through the notch becomes 225° with respect to a half line extending from the origin in the positive direction of the X axis.

Among the five measurement points, the second measurement point, the third measurement point, the fourth measurement point, and the fifth measurement point are disposed at equal intervals on a circumference consisting of a set of points each separated from the center of the GaAs single crystal substrate by D/4. Specifically, the coordinates (X, Y) of the second measurement point are set to (D/4, 0). The coordinates (X, Y) of the third measurement point are set to (0, D/4). The coordinates (X, Y) of the fourth measurement point are set to (−D/4, 0). The coordinates (X, Y) of the fifth measurement point are set to (0, −D/4). The D represents the diameter of the GaAs single crystal substrate, and the units of the D and each of the X and the Y in the coordinates (X, Y) are mm.

The GaAs single crystal substrate according to the second implementation has the diameter of 150 mm or more and 205 mm or less. In this case, on the main surface of the GaAs single crystal substrate according to the second implementation, four measurement points are further added in addition to the five measurement points set in the GaAs single crystal substrate according to the first implementation, and the total of nine measurement points are set as follows. That is, on the main surface of the GaAs single crystal substrate according to the second implementation, in addition to the second measurement point, the third measurement point, the fourth measurement point, and the fifth measurement point described above, four measurement targets each having a diameter of 20 mm are additionally set so as to be located on the outer peripheral side with respect to these measurement points and so as not to overlap with the measurement targets including the second measurement point, the third measurement point, the fourth measurement point, and the fifth measurement point. The center of each of the measurement targets is set as the measurement point, and X-ray is applied to the measurement point. Specifically, the coordinates (X, Y) of the sixth measurement point of the four added measurement points are set to (0, D/2-10). The coordinates (X, Y) of the seventh measurement point are set to (D/2-10, 0). The coordinates (X, Y) of the eighth measurement point are set to (−(D/2-10), 0). The coordinates (X, Y) of the ninth measurement point are set to (0, −(D/2-10)). The D represents the diameter of the GaAs single crystal substrate, and the units of the D and each of the X and the Y in the coordinates (X, Y) are mm.

It has been known that in a large-diameter main surface having a diameter of 150 mm or more and 205 mm or less such as the main surface of the GaAs single crystal substrate according to the second implementation, a property tends to be more varied at a region on the further outer peripheral side. Therefore, in order to evaluate the effect of reducing the haze value of the epitaxial film due to the uniform in-plane distribution of the third integrated intensity ratio, it is appropriate to determine the third integrated intensity ratio also at the region on the further outer peripheral side in addition to the above-described five measurement points and to thereby evaluate a variation thereof. In order to address this, in addition to the above-described five measurement points on the main surface of the GaAs single crystal substrate, four measurement targets each having a diameter of 20 mm and measurement points serving as the respective centers of the measurement targets are set at the region on the further outer peripheral side such that distances therebetween are as large as possible.

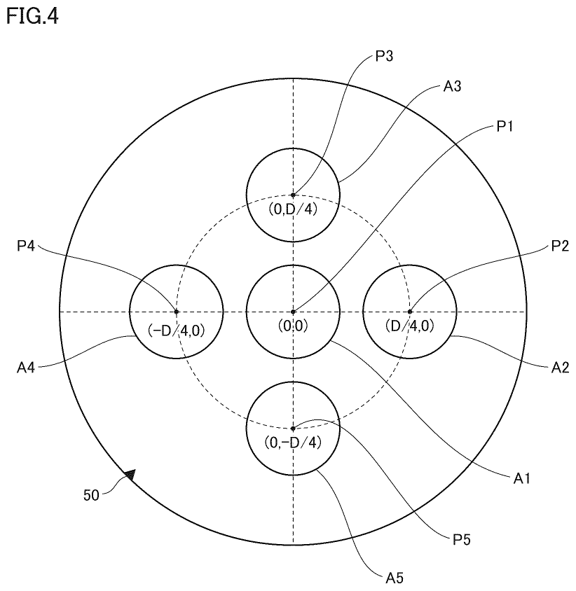

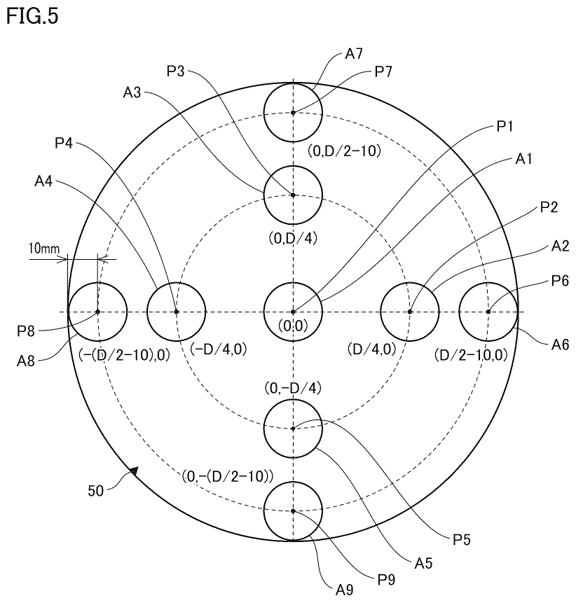

FIG. 4 is an explanatory diagram illustrating the five measurement points set in the gallium arsenide single crystal substrate having the diameter of 75 mm or more and less than 150 mm in the present embodiment. FIG. 5 is an explanatory diagram illustrating the nine measurement points set in the gallium arsenide single crystal substrate having the diameter of 150 mm or more and 205 mm or less in the present embodiment.

As shown in FIG. 4, in the GaAs single crystal substrate according to the first implementation, each of the X axis and the Y axis is set such that the general angle of the half line passing through notch 50 becomes 225° with respect to the half line extending from the origin in the positive direction of the X axis. Next, a first measurement point P1 is set at the origin (0, 0), which is the center of the GaAs single crystal substrate, and a measurement target A1, which is a circular region having a diameter of 20 mm and centered on first measurement point P1, is set.

Next, a second measurement point P2, a third measurement point P3, a fourth measurement point P4, and a fifth measurement point P5 are set on a circumference consisting of a set of points each separated from the center of the GaAs single crystal substrate by D/4. Further, a measurement target A2, a measurement target A3, a measurement target A4, and a measurement target A5, which are circular regions each having a diameter of 20 mm and respectively centered on second measurement point P2, third measurement point P3, fourth measurement point P4, and fifth measurement point P5, are set.

For example, when the example shown in FIG. 4 illustrates a GaAs single crystal substrate having a diameter of 75 mm, the coordinates (X, Y) (the units of X and Y are mm; the same applies to the description below) of second measurement point P2, third measurement point P3, fourth measurement point P4, and fifth measurement point P5 are set to (18.75, 0), (0, 18.75), (−18.75, 0), and (0, −18.75), respectively. Here, in the GaAs single crystal substrate having the diameter of 75 mm, measurement target A1 overlaps with measurement target A2, measurement target A3, measurement target A4, and measurement target A5 at some regions. However, such overlapping is acceptable because it is not disadvantageous from the viewpoint of evaluating the uniformity of the main surface of the GaAs single crystal substrate.

As shown in FIG. 5, in the GaAs single crystal substrate according to the second implementation, in addition to first measurement point P1 to fifth measurement point P5 set in the GaAs single crystal substrate according to the first implementation, a sixth measurement point P6, a seventh measurement point P7, an eighth measurement point P8, and a ninth measurement point P9, which are the four measurement points, are set at equal intervals on the circumference located on the outer peripheral side with respect to second measurement point P2, third measurement point P3, fourth measurement point P4, and fifth measurement point P5 and located inward by 10 mm from the outer periphery of the GaAs single crystal substrate. Further, a measurement target A6, a measurement target A7, a measurement target A8, and a measurement target A9, which are circular regions each having a diameter of 20 mm and respectively centered on sixth measurement point P6, seventh measurement point P7, eighth measurement point P8, and ninth measurement point P9, are set.

For example, when the example shown in FIG. 5 illustrates a GaAs single crystal substrate having a diameter of 150 mm, the coordinates (X, Y) of second measurement point P2, third measurement point P3, fourth measurement point P4, and fifth measurement point P5 are set to (37.5, 0), (0, 37.5), (−37.5, 0), and (0, 37.5), respectively. Further, the coordinates (X, Y) of sixth measurement point P6, seventh measurement point P7, eighth measurement point P8, and ninth measurement point P9 are set to (65, 0), (0, 65), (−65, 0), and (0, −65), respectively.

### <Epitaxial Film>

The GaAs single crystal substrate preferably has an epitaxial film disposed on the main surface. In this case, a maximum value of haze of a surface of the epitaxial film is preferably 350 ppm or less, and an average value of the haze of the surface of the epitaxial film is preferably 2.5 ppm or less. The maximum value of the haze of the surface of the epitaxial film is more preferably 100 ppm or less, and the average value of the haze of the surface of the epitaxial film is more preferably 2.0 ppm or less. The lower limit of each of the maximum value and the average value of the haze of the surface of the epitaxial film is 0, which is an ideal value.

The epitaxial film is, for example, a compound film composed of Al_{1-y-z}Ga_{y}In_{z}Aₛ, where y may be 0 or more and 1 or less, z may be 0 or more and 1 or less, and the sum of y and z may be 0 or more and 1 or less. That is, in the present embodiment, a compound film composed of Al_{1-y-z}Ga_{y}In_{z}Aₛ (0≤y≤1, 0≤z≤1, 0≤y+z≤1) can be applied as the epitaxial film formed on the main surface of the GaAs single crystal substrate. Further, the epitaxial film can be a compound film of AlₓGa₁₋ₓN (0≤x≤1) or AlₓGa₁₋ₓAₛ (0≤x≤1).

The epitaxial film is formed to have a thickness of, for example, 0.5 to 10 μm. When the thickness of the epitaxial film falls within the above range, the epitaxial substrate can be applied in a wide range of purposes of use. More preferably, the epitaxial film has a thickness of 1 to 5 μm.

The value of the haze of the epitaxial film disposed on the main surface of the GaAs single crystal substrate can be determined by a conventionally known surface foreign matter inspection apparatus (for example, trade name: “Surfscan 6420” provided by KLA-Tencor Corporation). The apparatus can perform measurement onto the entire surface of the epitaxial film (except for a region of 2 mm inward from the outer periphery of the substrate), and can measure the value of the haze (amount of scattered light (ppm)) per cm² on the surface of the epitaxial film. Based on a result of such measurement, each of the maximum value and the average value of the haze of the surface of the epitaxial film can be determined.

### [Method of Producing Gallium Arsenide Single Crystal Substrate]

A method of producing a gallium arsenide single crystal substrate (GaAs single crystal substrate) according to the present embodiment is preferably a production method of producing the GaAs single crystal substrate described above. For example, the production method includes: a step (preparation step) of preparing a gallium arsenide single crystal substrate precursor (hereinafter, also referred to as “GaAs single crystal substrate precursor”) having a surface having a circular shape; and a cleaning step of obtaining the GaAs single crystal substrate from the GaAs single crystal substrate precursor. The cleaning step includes: a step (surface polishing step) of forming the surface of the GaAs single crystal substrate precursor into a polished surface by polishing the surface; a step (alkali cleaning step) of forming the polished surface into an alkali-cleaned surface by cleaning the polished surface with an alkali cleaning liquid; a step (first acid cleaning step) of forming the alkali-cleaned surface into a first acid-cleaned surface by cleaning the alkali-cleaned surface with an acid cleaning liquid including 0.3 ppm by mass or more and 1 mass % or less of a first acid; a step (second acid cleaning step) of forming the first acid-cleaned surface into a second acid-cleaned surface by immersing the first acid-cleaned surface in more than 0.5 mass % and 1 mass % or less of a second acid for 1 minute or more; and a step (heat treatment step) of forming the second acid-cleaned surface into the main surface by performing heat treatment onto the second acid-cleaned surface in an inert gas atmosphere under conditions of 100° C. or more and 200° C. or less and 1 minute or more and 30 minutes or less. The second acid includes at least one selected from a group consisting of hydrofluoric acid, hydrochloric acid, nitric acid, and nitrous acid. With the production method having such a feature, it is possible to obtain a gallium arsenide single crystal substrate having a main surface with an oxide film that can be effectively removed using the thermal cleaning. The production method preferably includes a step (epitaxial film formation step) of forming an epitaxial film on the main surface. Thus, it is possible to obtain the gallium arsenide single crystal substrate having the main surface on which the epitaxial film having a reduced value of haze is formed.

In the present specification, the term “gallium arsenide single crystal substrate precursor (GaAs single crystal substrate precursor)” refers to a GaAs single crystal substrate that has a surface having a circular shape and that is cut out from a gallium arsenide single crystal (hereinafter, also referred to as “GaAs single crystal”) produced by a conventionally known production method such as a vertical boat method, and particularly refers to a GaAs single crystal substrate to be subjected to each step included in the cleaning step.

The present inventors have paid attention to modifying a conventionally known cleaning step of obtaining a GaAs single crystal substrate, based on the knowledge obtained based on the analysis through the above-described XPS using synchrotron radiation. In particular, it has been known that the oxide film of the GaAs single crystal substrate is formed by oxidizing the surface in the acid cleaning step of removing an impurity in an alkali cleaning agent adhered to the surface of the GaAs single crystal substrate precursor after the alkali cleaning. Therefore, attention is paid to performing, after the acid cleaning step, a process to provide the oxide film with a composition rich in As₂O₅ in the vicinity of the interface between the oxide film and the layer composed of GaAs and included in the GaAs single crystal substrate. Specifically, by further performing acid cleaning onto the surface after the above-described acid cleaning step, progress of oxidation reaction of the GaAs is caused to segregate, in the surface, an oxide film including the As₂O₃ as a main component, and then heat treatment was performed onto the surface. Thus, it has been found that an oxidation-reduction reaction occurs between the As₂O₃ and the GaAs in the vicinity of the interface, the As is sublimated, and the As₂O₅ is secondarily generated, with the result that the vicinity of the interface has the composition rich in the As₂O₅. In such a GaAs single crystal substrate, progress of oxidation of the oxide film with passage of time is suppressed, and the oxide film can be therefore effectively removed using the thermal cleaning. Thus, the present inventors could obtain the GaAs single crystal substrate having the main surface having the high mirror surface property, thereby arriving at the method of producing the GaAs single crystal substrate on which an epitaxial film having a reduced value of haze can be formed.

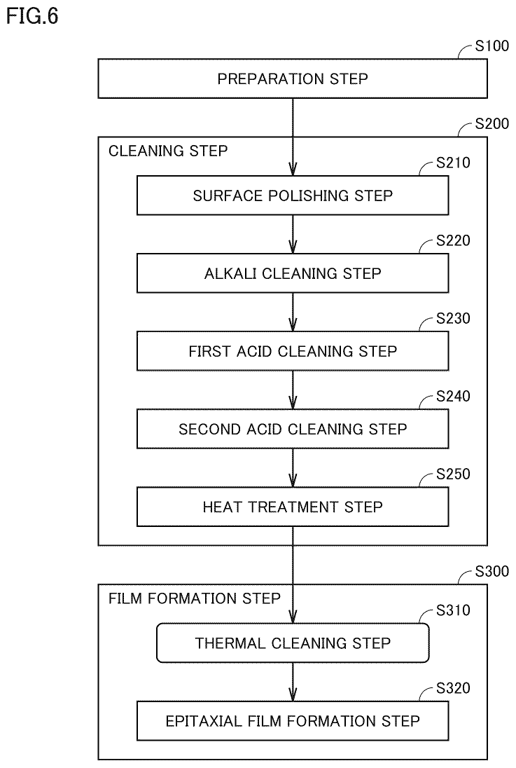

Hereinafter, each of the steps included in the method of producing the GaAs single crystal substrate according to the present embodiment will be specifically described with reference to FIG. 6. FIG. 6 is a flowchart showing the method of producing the gallium arsenide single crystal substrate according to the present embodiment.

### <Preparation Step S100>

The method of producing the GaAs single crystal substrate includes the step (preparation step S100) of preparing the GaAs single crystal substrate precursor having the surface having the circular shape. In preparation step S100, the GaAs single crystal substrate precursor required to perform the cleaning step is prepared. Preparation step S100 can include a step of performing a conventionally known method of producing a GaAs single crystal substrate precursor. That is, preparation step S100 can include a step of producing a gallium arsenide single crystal (hereinafter, also referred to as “GaAs single crystal”) using a conventionally known production method such as a vertical boat method and cutting out a GaAs single crystal substrate precursor having a surface having a circular shape from the GaAs single crystal. Preparation step S100 can also include a step of processing, into a desired size (for example, a disk shape having a diameter of 2 to 6 inches and a thickness of 250 to 1500 μm), the GaAs single crystal substrate precursor cut out from the GaAs single crystal. As the processing method, a conventionally known method such as slicing or chamfering can be used.

### <Cleaning Step S200>

The method of producing the GaAs single crystal substrate includes cleaning step S200 of obtaining the GaAs single crystal substrate from the GaAs single crystal substrate precursor. With this cleaning step S200, the GaAs single crystal substrate having the main surface with the oxide film that can be effectively removed using the thermal cleaning can be obtained from the GaAs single crystal substrate precursor. Cleaning step S200 includes: the step (surface polishing step S210) of forming the surface of the GaAs single crystal substrate precursor into a polished surface by polishing the surface; the step (alkali cleaning step S220) of forming the polished surface into an alkali-cleaned surface by cleaning the polished surface with an alkali cleaning liquid; the step (first acid cleaning step S230) of forming the alkali-cleaned surface into a first acid-cleaned surface by cleaning the alkali-cleaned surface with an acid cleaning liquid including 0.3 ppm by mass or more and 1 mass % or less of a first acid; the step (second acid cleaning step S240) of forming the first acid-cleaned surface into a second acid-cleaned surface by immersing the first acid-cleaned surface in more than 0.5 mass % and 1 mass % or less of a second acid for 1 minute or more; and the step (heat treatment step S250) of forming the second acid-cleaned surface into the main surface by performing heat treatment onto the second acid-cleaned surface in an inert gas atmosphere under conditions of 100° C. or more and 200° C. or less and 1 minute or more and 30 minutes or less. Hereinafter, each of the steps included in cleaning step S200 will be described in detail.

### (Surface Polishing Step S210)

Surface polishing step S210 is the step of forming the surface of the GaAs single crystal substrate precursor into the polished surface by polishing the surface. By surface polishing step S210, the surface of the GaAs single crystal substrate precursor is formed into a mirror-finished polished surface. For example, by surface polishing step S210, the surface of the GaAs single crystal substrate precursor can be formed into a polished surface having a surface roughness of 0.3 nm or less, which is expressed by an arithmetic mean roughness Ra. As a polishing method in surface polishing step S210, various polishing methods can be used, such as conventionally known mechanical polishing and chemical mechanical polishing.

### (Alkali Cleaning Step S220)

Alkali cleaning step S220 is the step of forming the polished surface into the alkali-cleaned surface by cleaning the polished surface with the alkali cleaning liquid. By alkali cleaning step S220, a foreign matter, impurity, or the like adhered to the polished surface of the GaAs single crystal substrate precursor can be removed using the alkali cleaning liquid. The alkali cleaning liquid is not particularly limited, but an aqueous solution including 0.1 to 10 mass % of an organic alkali compound not including a metal element that affects the electrical property is preferably used, and examples of the organic alkali compound include a quaternary ammonium hydroxide such as choline or tetramethylammonium hydroxide (TMAH), a quaternary pyridinium hydroxide, or the like.

### (First Acid Cleaning Step S230)

First acid cleaning step S230 is the step of forming the alkali-cleaned surface into the first acid-cleaned surface by cleaning the alkali-cleaned surface with the acid cleaning liquid including 0.3 mass ppm or more and 1 mass % or less of the first acid. By first acid cleaning step S230, an impurity included in the alkali cleaning liquid and adhered to the alkali-cleaned surface of the GaAs single crystal substrate precursor can be removed by an oxidation reaction (etching of the alkali-cleaned surface) with the acid cleaning liquid. In particular, in first acid cleaning step S230, the alkali-cleaned surface is cleaned with the acid cleaning liquid including 0.3 mass ppm or more and 1 mass % or less of the first acid. Thus, the ratio of the Ga atoms and the As atoms in the main surface becomes appropriate and the generation of excess of the oxide film is suppressed, with the result that the oxide film can be efficiently removed by the thermal cleaning. In first acid cleaning step S230, the alkali-cleaned surface is more preferably cleaned with an acid cleaning liquid including 0.3 mass ppm or more and 0.5 mass % or less of the first acid.

When the acid concentration of the first acid in the acid cleaning liquid is less than 0.3 mass ppm, a modifying action on the alkali-cleaned surface becomes small. On the other hand, an influence of carbon dioxide (CO₂) gas dissolved in the acid cleaning liquid from an atmospheric atmosphere becomes large, thereby causing a variation in chemical composition of the first acid-cleaned surface after first acid cleaning step S230. When the acid concentration of the first acid in the acid cleaning liquid is more than 1 mass %, deviation of the first acid-cleaned surface from the stoichiometry is large due to the action of the first acid just after first acid cleaning step S230. On this occasion, the chemical composition of the first acid-cleaned surface is richer in As than in Ga. However, the chemical composition of the first acid-cleaned surface is conversely changed to become richer in Ga due to carbon dioxide gas or the like present in an atmosphere at the time of subsequent drying or transportation. Hence, as a result, the chemical composition of the first acid-cleaned surface (and the main surface in the subsequent step) tends to be varied. Here, the term “stoichiometry” means that when a certain compound is present, a ratio (composition) of the numbers of atoms constituting the compound is the same as in the chemical formula.

The first acid included in the acid cleaning liquid is not particularly limited, but is preferably an acid component that has a high cleaning power, that does not include an element (for example, a metal element, sulfur, or the like) affecting the electrical property, and that is less likely to cause serious secondary contamination and facility deterioration in response to evaporation of the acid component together with a water component when droplets are scattered in the facility. For example, the first acid preferably includes at least one inorganic acid selected from a group consisting of hydrofluoric acid (HF), hydrochloric acid (HCl), nitric acid (HNO₃), and nitrous acid (HNO₂). As the first acid, an organic acid such as acetic acid, citric acid, or malic acid can also be preferably used. Further, two or more of these acids may be used in combination, for example, the hydrochloric acid and the nitric acid may be used in combination.

From the viewpoint of the cleaning property, the acid cleaning liquid more preferably includes 0.3 mass ppm to 0.3 mass % of hydrogen peroxide (H₂O₂). When the concentration of the H₂O₂ is less than 0.3 mass ppm, an influence of dissolved oxygen in the acid cleaning liquid may become large, with the result that the effect of promoting the removal of the impurity may be reduced. When the concentration of the H₂O₂ is more than 0.3 mass %, an etching rate may become too high, with the result that an etching level difference may be caused in the first acid-cleaned surface.

In first acid cleaning step S230, the acid cleaning liquid can be supplied to the alkali-cleaned surface while rotating the GaAs single crystal substrate precursor at 100 rpm or more and 800 rpm or less with the surface thereof being held to be horizontal. Thus, a film of the acid cleaning liquid on the alkali-cleaned surface can formed, thereby performing efficient acid cleaning while suppressing excessive oxidation of the alkali-cleaned surface. When the rotation speed of the GaAs single crystal substrate precursor is less than 100 rpm, the cleaning efficiency may be unable to be improved, whereas when the rotation speed is more than 800 rpm, the film of the acid cleaning liquid may be unable to be formed and the effect of suppressing the oxidation may be reduced.

Further, after first acid cleaning step S230, preferably immediately after first acid cleaning step S230, the first acid-cleaned surface of the GaAs single crystal substrate precursor is preferably cleaned using pure water. The cleaning method using pure water is not particularly limited, but the first acid-cleaned surface of the GaAs single crystal substrate precursor is preferably cleaned for 5 minutes or less with pure water having a dissolved oxygen concentration (DO) of 100 ppb or less. Thus, progress of excessive oxidation of the first acid-cleaned surface can be suppressed. Here, the dissolved oxygen concentration of the pure water is more preferably 50 ppb or less from the viewpoint of further suppressing the progress of the excessive oxidation. A total organic carbon (TOC) of the pure water is preferably 40 ppb or less from the viewpoint of a small amount of impurity. The cleaning method using pure water can also be performed by supplying the pure water to the first acid-cleaned surface while rotating the GaAs single crystal substrate precursor at 100 rpm or more and 800 rpm or less with the main surface thereof being held to be horizontal.

### (Second Acid Cleaning Step S240)

Second acid cleaning step S240 is a step of forming the first acid-cleaned surface into a second acid-cleaned surface by immersing the first acid-cleaned surface in more than 0.5 mass % and 1 mass % or less of a second acid for 1 minute or more. By second acid cleaning step S240, the oxidation reaction of the GaAs in the first acid-cleaned surface can be further proceeded, with the result that an oxide film including As₂O₃ as a main component can be segregated in the first acid-cleaned surface. Thus, in heat treatment step S250 described later, an oxidation-reduction reaction occurs between the As₂O₃ and the GaAs in the vicinity of the interface between the oxide film and the layer composed of the GaAs in the GaAs single crystal substrate precursor, thereby generating the As₂O₅ in the vicinity of the interface.

In particular, in second acid cleaning step S240, the first acid-cleaned surface is immersed in more than 0.5 mass % and 1 mass % or less of the second acid for 1 minute or more. Thus, the oxidation reaction of the GaAs in the first acid-cleaned surface is further proceeded, with the result that the second acid-cleaned surface in which the oxide film is formed can be obtained. When the acid concentration of the second acid in the acid cleaning liquid is 0.5 mass % or less, a modifying action (oxidizing action) on the first acid-cleaned surface becomes small. On the other hand, when the acid concentration of the second acid in the acid cleaning liquid is more than 1 mass %, the oxidation reaction of the GaAs is excessively proceeded in the first acid-cleaned surface, with the result that it may become difficult to remove the whole of the oxide film by the thermal cleaning. In second acid cleaning step S240, the first acid-cleaned surface is further preferably immersed in 0.7 mass % or less and 1 mass % or less of the second acid for 1 minute or more.

In second acid cleaning step S240, the time (immersion time) for immersing the first acid-cleaned surface in the second acid is 1 minute or more as described above, is preferably 1 minute or more and 30 minutes or less, and is more preferably 1 minute or more and 5 minutes or less. When the immersion time is less than 1 minute, the modifying action (oxidizing action) on the first acid-cleaned surface becomes small. When the immersion time is more than 30 minutes, a disadvantage that the time spent in cleaning step S200 is increased may be larger than the advantage of the modifying action on the first acid-cleaned surface.

The second acid includes at least one selected from a group consisting of hydrofluoric acid, hydrochloric acid, nitric acid, and nitrous acid. Each of these acids is preferable because it has a high cleaning power, does not include an element (for example, a metal element, sulfur, or the like) affecting the electrical property, and is less likely to cause serious secondary contamination and facility deterioration in response to evaporation of the acid component together with a water component when droplets are scattered in the facility. In addition to the acids described above, the second acid can also be used in combination of organic acids such as acetic acid, citric acid, and malic acid. As the second acid, two or more of the above-described acids can also be used in combination. For example, as the second acid, the hydrochloric acid and the nitric acid can also be used in combination.

Further, after second acid cleaning step S240, preferably immediately after second acid cleaning step S240, the second acid-cleaned surface of the GaAs single crystal substrate precursor is preferably cleaned using pure water. The cleaning method using pure water is not particularly limited, but the second acid-cleaned surface of the GaAs single crystal substrate precursor is preferably cleaned for 5 minutes or less with pure water having a dissolved oxygen concentration (DO) of 100 ppb or less. Thus, progress of excessive oxidation of the second acid-cleaned surface can be suppressed. Here, the dissolved oxygen concentration of the pure water is more preferably 50 ppb or less from the viewpoint of further suppressing the progress of the excessive oxidation. A total organic carbon (TOC) of the pure water is preferably 40 ppb or less from the viewpoint of a small amount of impurity. The cleaning method using pure water can also be performed by supplying the pure water to the second acid-cleaned surface while rotating the GaAs single crystal substrate precursor at 100 rpm or more and 800 rpm or less with the main surface thereof being held to be horizontal.

### (Heat Treatment Step S250)

Heat treatment step S250 is a step of forming the second acid-cleaned surface into the main surface by performing heat treatment onto the second acid-cleaned surface in an inert gas atmosphere under conditions of 100° C. or more and 200° C. or less and 1 minute or more and 30 minutes or less. By heat treatment step S250, the As₂O₅ can be generated by causing an oxidation-reduction reaction between the As₂O₃ and the GaAs in the vicinity of the interface between the oxide film including, as a main component, the As₂O₃ segregated in the second acid-cleaned surface and the layer composed of the GaAs in the GaAs single crystal substrate precursor. Thus, a GaAs single crystal substrate having a main surface including an oxide film rich in As₂O₅ in the vicinity of the interface can be obtained. Since the progress of the oxidation of the oxide film with passage of time is suppressed in the GaAs single crystal substrate, the oxide film can be effectively removed using the thermal cleaning.

In heat treatment step S250, the heat treatment is performed onto the second acid-cleaned surface in the inert gas atmosphere under conditions of 100° C. or more and 200° C. or less and 1 minute or more and 30 minutes or less. The type of the inert gas is not particularly limited, but argon or nitrogen is preferable. The temperature for the heat treatment is preferably 125 to 175° C. The time for the heat treatment is preferably performed for 10 to 20 minutes. By performing the heat treatment under the above-described conditions, the As₂O₅ can be appropriately generated in the vicinity of the interface between the oxide film and the layer composed of the GaAs. When the temperature for the heat treatment is less than 125° C. or the time for the heat treatment is less than 1 minute, it tends to be difficult to sufficiently generate the As₂O₅ in the vicinity of the interface. When the temperature for the heat treatment is more than 175° C. or the time for the heat treatment is more than 30 minutes, the GaAs single crystal substrate may be adversely affected by the excessive heating.

### <Film Formation Step S300>

### (Thermal Cleaning Step S310)

As described above, in the method of producing the GaAs single crystal substrate according to the present embodiment, the GaAs single crystal substrate having the main surface including the oxide film rich in As₂O₅ in the vicinity of the interface between the oxide film and the main layer composed of the GaAs can be obtained. The GaAs single crystal substrate is preferably subjected to a thermal cleaning step S310 and an epitaxial film formation step S320 described below as a film formation step S300. Even when the thermal cleaning is performed onto the GaAs single crystal substrate under conventionally known conditions (for example, conditions of heat treatment at 550° C. for 5 minutes) in thermal cleaning step S310, the progress of the oxidation of the oxide film with passage of time is suppressed, with the result that the oxide film can be effectively removed.

### <Epitaxial Film Formation Step S320>

Further, the method of producing the GaAs single crystal substrate according to the present embodiment preferably includes the step (epitaxial film formation step S320) of forming an epitaxial film on the main surface as described above. By epitaxial film formation step S320, the GaAs single crystal substrate having the main surface on which an epitaxial film having a reduced value of haze is formed can be obtained. For example, a maximum value of haze of a surface of the epitaxial film can be 350 ppm or less, and an average value of the haze of the surface can be 2.5 ppm or less, thereby attaining an improved device property.

As a method of forming the epitaxial film on the main surface of the GaAs single crystal substrate in epitaxial film formation step S320, a conventionally known method can be used. The property of the epitaxial film obtained in this step is the same as that described in the section <Epitaxial Film> above, and therefore the same explanation will not be described repeatedly. Since the gallium arsenide single crystal substrate having the main surface on which the epitaxial film is formed has a sufficiently small value of haze, the gallium arsenide single crystal substrate can be applied to devices such as a field effect transistor, and a microwave diode, other integrated circuits, and the like as purposes of use.

### Examples

Hereinafter, the present disclosure will be described more in detail with reference to examples, but the present disclosure is not limited thereto.

### [First Test]

GaAs single crystal substrates of samples 1 to 7 described below are examples of the present disclosure, and GaAs single crystal substrates of samples 11 to 13 are comparative examples.

### <Production of GaAs Single Crystal Substrate>

### (Sample 1)

### 1) Preparation Step

A plurality of GaAs single crystal substrate precursors each having a diameter of 6 inches (150 mm) and a thickness of 675 μm were each prepared by slicing and chamfering a semi-insulating GaAs single crystal having carbon (C) atoms added therein and grown by the Vertical Bridgman (VB) method.

### 2) Surface Polishing Step

A surface of each of the GaAs single crystal substrate precursors was subjected to conventionally known mechanical polishing and chemical mechanical polishing. Thus, the GaAs single crystal substrate precursor having a polished surface having an arithmetic mean roughness Ra of 0.3 nm or less as defined in JIS B0601:2001 and having an off angle of 2° with respect to the (100) plane was produced.

### 3) Alkali Cleaning Step

The polished surface of the GaAs single crystal substrate precursor was immersed in an aqueous solution including 0.5 mass % of tetramethylammonium hydroxide, at room temperature (25° C.) for 10 minutes in accordance with a vertical batch method. Thereafter, the GaAs single crystal substrate precursor was rinsed for 3 minutes with ultrapure water (electrical resistivity (specific resistance) is 18 MΩ·cm or more, TOC (total organic carbon) is less than 10 μg/liter, and the number of fine particles is less than 100 particles/liter; the same applies to the description below).

### 4) First Acid Cleaning Step

The alkali-cleaned surface of the GaAs single crystal substrate precursor was subjected to acid cleaning in accordance with the vertical batch method using an acid cleaning liquid including a first acid. In the acid cleaning, the alkali-cleaned surface of the GaAs single crystal substrate precursor was immersed, at room temperature (25° C.) for 2 minutes, in an aqueous hydrochloric acid solution including 0.3 mass ppm of hydrochloric acid as the first acid. Further, the GaAs single crystal substrate precursor was rinsed for 3 minutes with the same ultrapure water as the ultrapure water used in the alkali cleaning step. Thus, the alkali-cleaned surface was formed into a first acid-cleaned surface.

### 5) Second Acid Cleaning Step

The first acid-cleaned surface of the GaAs single crystal substrate precursor was subjected to acid cleaning in accordance with the vertical batch method using an acid cleaning liquid including a second acid. Specifically, the first acid-cleaned surface of the GaAs single crystal substrate precursor was immersed in an aqueous hydrochloric acid solution including 0.6 mass % of hydrochloric acid as the second acid for 10 minutes. Then, the GaAs single crystal substrate precursor was rinsed for 3 minutes with the same ultrapure water as the ultrapure water used in the alkali cleaning step. Thus, the first acid-cleaned surface was formed into the second acid-cleaned surface.

### 6) Heat Treatment Step

The second acid-cleaned surface of the GaAs single crystal substrate precursor was subjected to heat treatment under an argon gas atmosphere at 100° C. for 30 minutes. Thus, the second acid-cleaned surface was formed into a main surface having a predetermined oxide film. In this way, a required number of GaAs single crystal substrates of a sample 1 were obtained. In each of the GaAs single crystal substrates, the diameter and thickness of the GaAs single crystal substrate precursor were maintained.

### 7) Epitaxial Film Formation Step

The GaAs single crystal substrate was subjected to thermal cleaning at 550° C. for 5 minutes. Further, an Al_{0.5}Ga_{0.5}As layer having a thickness of 5 μm was grown by a metalorganic vapor phase epitaxy method (MOVPE method) as an epitaxial layer on the main surface of one of the GaAs single crystal substrates each having been through the thermal cleaning (hereinafter, the GaAs single crystal substrate having the main surface on which the epitaxial layer is grown is also referred to as “epitaxial substrate”). In this way, the epitaxial substrate of sample 1 was obtained. When growing the epitaxial layer, the GaAs single crystal substrate was heated to 550° C.

### (Sample 2)

A required number of GaAs single crystal substrates of a sample 2 were obtained in the same manner as in sample 1, except that in the second acid cleaning step, the first acid-cleaned surface of the GaAs single crystal substrate precursor was immersed in an aqueous hydrochloric acid solution including 0.8 mass % of hydrochloric acid as a second acid for 5 minutes, and in the heat treatment step, the second acid-cleaned surface of the GaAs single crystal substrate precursor was subjected to heat treatment in an argon gas atmosphere at 130° C. for 20 minutes. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 2.

### (Sample 3)

A required number of GaAs single crystal substrates of a sample 3 were obtained in the same manner as in sample 2, except that in the heat treatment step, the second acid-cleaned surface of the GaAs single crystal substrate precursor was subjected to heat treatment in an argon gas atmosphere at 160° C. for 10 minutes. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 3.

### (Sample 4)

A required number of GaAs single crystal substrates of a sample 4 were obtained in the same manner as in sample 1, except that in the second acid cleaning step, the first acid-cleaned surface of the GaAs single crystal substrate precursor was immersed in an aqueous hydrochloric acid solution including 0.8 mass % of hydrochloric acid as a second acid for 5 minutes, and in the heat treatment step, the second acid-cleaned surface of the GaAs single crystal substrate precursor was subjected to heat treatment in an argon gas atmosphere at 100° C. for 30 minutes. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 4.

### (Sample 5)

A required number of GaAs single crystal substrates of a sample 5 were obtained in the same manner as in sample 1, except that in the heat treatment step, the second acid-cleaned surface of the GaAs single crystal substrate precursor was subjected to heat treatment in an argon gas atmosphere at 150° C. for 15 minutes. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 5.

### (Sample 6)

A required number of GaAs single crystal substrates of a sample 6 were obtained in the same manner as in sample 1, except that in the heat treatment step, the second acid-cleaned surface of the GaAs single crystal substrate precursor was subjected to heat treatment in an argon gas atmosphere at 100° C. for 10 minutes. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 6.

### (Sample 11)

A required number of GaAs single crystal substrates of a sample 11 were obtained in the same manner as in sample 1 except that the second acid cleaning step and the heat treatment step were not performed. Further, an Al_{0.5}Ga_{0.5}As layer having a thickness of 5 μm was grown as an epitaxial layer on the main surface of one of the GaAs single crystal substrates in the same manner as in sample 1, thereby obtaining an epitaxial substrate of sample 11.

### <Maximum Value and Average Value of Haze of Surface of Epitaxial Film>

For the surface of the epitaxial film in each of the epitaxial substrates of samples 1 to 6 and sample 11, a maximum value and an average value of haze of a surface of the epitaxial film in each sample were determined by using a surface foreign matter inspection apparatus (trade name: “Surfscan 6420” provided by KLA-Tencor Corporation). The result is shown in Table 1.

Further, based on the values of the maximum value and the average value of the haze of the surface of the epitaxial film, quality of the epitaxial substrate of each of samples 1 to 6 and sample 11 was determined based on the following criteria. The result is shown in Table 1.
A: the maximum value of the haze is 100 ppm or less and the average value of the haze is 2.0 ppm or less;
B: the maximum value of the haze is more than 100 ppm and 350 ppm or less and the average value of the haze is 2.5 ppm or less; and
C: at least the maximum value of the haze is more than 350 ppm or the average value of the haze is more than 2.5 ppm.

### <Analysis on GaAs Single Crystal Substrate Using X-Ray Photoelectron Spectroscopy>

Each of X-ray having an energy of 150 eV and X-ray having an energy of 600 eV was prepared by utilizing “BL17”, which is one of beamlines only for Sumitomo Electric Industries in SAGA Light Source. The X-ray is applied to the center of the main surface of each of the GaAs single crystal substrates of samples 1 to 6 and sample 11, thereby performing an analysis using X-ray photoelectron spectroscopy. It should be noted that since each of the GaAs single crystal substrates of samples 1 to 6 and sample 11 could not be entirely placed on a sample stage, a test piece was cut out from each of the GaAs single crystal substrates of samples 1 to 6 and sample 11, and the analysis was performed onto the test piece.

Analysis conditions are as follows.
Condition 1: X-ray incident energy of 150 eV and photoelectron take-off angle of 30°.
Condition 2: X-ray incident energy of 150 eV and photoelectron take-off angle of 45°.
Condition 3: X-ray incident energy of 150 eV and photoelectron take-off angle of 85°.
Condition 4: X-ray incident energy of 600 eV and photoelectron take-off angle of 30°.
Condition 5: X-ray incident energy of 600 eV and photoelectron take-off angle of 45°.
Condition 6: X-ray incident energy of 600 eV and photoelectron take-off angle of 85°.
Size of the test piece under each condition: 10 mm×10 mm
Pressure around the test piece under each condition: 4×10⁻⁷ Pa
High-resolution XPS analyzer (trade name: “R3000” provided by Scienta Omicron) used under each condition
Energy resolution E/ΔE: 3480
Plot interval for coupling energy: 0.02 eV
Integration time and number of times of integrations at each energy value: 100 ms and 50 times.

Based on the As3d spectrums obtained by the analyses under the above conditions (conditions 1 to 6), R1, R2, R3, R4, R5, and R6, each of which is the first integrated intensity ratio, were determined, the first integrated intensity ratio being the ratio of the integrated intensity of the As element (As⁵⁺) present as the As₂O₅ to the sum of the integrated intensity of the As element (As⁵⁺) present as the As₂O₅, the integrated intensity of the As element (As³⁺) present as the As₂O₃, the integrated intensity of the As element (Ga—As) present as the GaAs, and the integrated intensity of the As element (metal As) present as the metal As. The results are shown in Table 1. In Table 1, a ratio of the integrated intensity of the As³⁺ to the sum of the integrated intensity of As5+, the integrated intensity of the As³⁺, the integrated intensity of the Ga—As, and the integrated intensity of the metal As is also shown in addition to first integrated intensity ratios R1, R2, R3, R4, R5, and R6. Further, a ratio of the integrated intensity of the metal As to the sum of the integrated intensity of the As⁵⁺, the integrated intensity of the As³⁺, the integrated intensity of the Ga—As, and the integrated intensity of the metal As is also shown.

TABLE 1

| Sample | Type of | 150 eV | | | 600 eV | | | haze (ppm) | | |
|---|---|---|---|---|---|---|---|---|---|---|
| No. | Arsenic | 30° | 45° | 85° | 30° | 45° | 85° | Max | Ave | Determination |
| 1 | As⁵⁺ | 0.33 | 0.38 | 0.51 | 0.30 | 0.15 | 0.10 | 311 | 2.3 | B |
| | | (R1) | (R2) | (R3) | (R4) | (R5) | (R6) | | | |
| | As³⁺ | 0.64 | 0.57 | 0.38 | 0.41 | 0.31 | 0.25 | | | |
| | Metal As | 0.01 | 0.01 | 0.02 | 0.04 | 0.10 | 0.07 | | | |
| 2 | As⁵⁺ | 0.30 | 0.33 | 0.41 | 0.18 | 0.16 | 0.16 | 14 | 1.05 | A |
| | | (R1) | (R2) | (R3) | (R4) | (R5) | (R6) | | | |
| | As³⁺ | 0.60 | 0.54 | 0.41 | 0.46 | 0.37 | 0.24 | | | |
| | Metal As | 0.02 | 0.02 | 0.04 | 0.07 | 0.10 | 0.09 | | | |
| 3 | As⁵⁺ | 0.32 | 0.36 | 0.43 | 0.20 | 0.10 | 0.10 | 23 | 1.1 | A |
| | | (R1) | (R2) | (R3) | (R4) | (R5) | (R6) | | | |
| | As³⁺ | 0.65 | 0.56 | 0.43 | 0.40 | 0.32 | 0.26 | | | |
| | Metal As | 0.01 | 0.01 | 0.02 | 0.04 | 0.10 | 0.07 | | | |
| 4 | As⁵⁺ | 0.28 | 0.36 | 0.35 | 0.23 | 0.11 | 0.09 | 231 | 1.7 | B |
| | | (R1) | (R2) | (R3) | (R4) | (R5) | (R6) | | | |
| | As³⁺ | 0.61 | 0.45 | 0.41 | 0.38 | 0.36 | 0.30 | | | |
| | Metal As | 0.01 | 0.02 | 0.03 | 0.07 | 0.07 | 0.05 | | | |
| 5 | As⁵⁺ | 0.21 | 0.28 | 0.30 | 0.31 | 0.15 | 0.12 | 145 | 1.8 | B |
| | | (R1) | (R2) | (R3) | (R4) | (R5) | (R6) | | | |
| | As³⁺ | 0.73 | 0.58 | 0.50 | 0.38 | 0.32 | 0.28 | | | |
| | Metal As | 0.01 | 0.02 | 0.03 | 0.07 | 0.07 | 0.05 | | | |
| 6 | As⁵⁺ | 0.15 | 0.17 | 0.25 | 0.20 | 0.14 | 0.11 | 285 | 2 | B |
| | | (R1) | (R2) | (R3) | (R4) | (R5) | (R6) | | | |
| | As³⁺ | 0.77 | 0.69 | 0.54 | 0.47 | 0.31 | 0.27 | | | |
| | Metal As | 0.01 | 0.02 | 0.03 | 0.07 | 0.07 | 0.05 | | | |
| 11 | As⁵⁺ | 0.43 | 0.43 | 0.38 | 0.23 | 0.19 | 0.17 | >10000 | 393 | C |
| | | (R1) | (R1) | (R3) | (R4) | (R5) | (R6) | | | |
| | As³⁺ | 0.49 | 0.45 | 0.44 | 0.41 | 0.34 | 0.23 | | | |
| | Metal As | 0.02 | 0.02 | 0.03 | 0.09 | 0.10 | 0.10 | | | |

### <Review>

According to Table 1 above, the quality was determined to be A or B in each of the epitaxial substrates of samples 1 to 6 each satisfying the relation in which at least one of R2, R3, and R4 is the largest among R1, R2, R3, R4, R5, and R6 with regard to first integrated intensity ratios R1, R2, R3, R4, R5, and R6. On the other hand, the quality was determined to be C in the epitaxial substrate of sample 11 that did not satisfy the above relation. It should be noted that a GaAs single crystal substrate in which R5 or R6 is the largest among first integrated intensity ratios R1 to R6 is an example in which no oxide film or a very thin oxide film is present in the main surface, is not realistic, and is therefore not shown as a sample.

### [Second Test]

Each of GaAs single crystal substrates of samples 21 to 24 described below is an example of the present disclosure.

### <Production of GaAs Single Crystal Substrate>

### (Sample 21)

### 1) Preparation Step

One GaAs single crystal substrate precursor having a diameter of 3 inches (76.5 mm) and a thickness of 350 μm was prepared by slicing and chamfering a semi-insulating GaAs single crystal having carbon (C) atoms added therein and grown by the Vertical Bridgman (VB) method.

### 2) Surface Polishing Step

A surface of each of the GaAs single crystal substrate precursors was subjected to conventionally known mechanical polishing and chemical mechanical polishing. Thus, the GaAs single crystal substrate precursor having a polished surface having an arithmetic mean roughness Ra of 0.3 nm or less as defined in JIS B0601:2001 and having an off angle of 2° with respect to the (100) plane was produced.

### 3) Alkali Cleaning Step

The polished surface of the GaAs single crystal substrate precursor was immersed in an aqueous solution including 0.5 mass % of tetramethylammonium hydroxide, at room temperature (25° C.) for 10 minutes in accordance with a vertical batch method. Thereafter, the GaAs single crystal substrate precursor was rinsed for 3 minutes with ultrapure water (electrical resistivity (specific resistance) is 18 MΩ·cm or more, TOC (total organic carbon) is less than 10 μg/liter, and the number of fine particles is less than 100 particles/liter; the same applies to the description below).

### 4) First Acid Cleaning Step

The alkali-cleaned surface of the GaAs single crystal substrate precursor was subjected to acid cleaning in accordance with the vertical batch method using an acid cleaning liquid including a first acid. In the acid cleaning, the alkali-cleaned surface of the GaAs single crystal substrate precursor was immersed, at room temperature (25° C.) for 2 minutes, in an aqueous hydrochloric acid solution including 0.3 mass ppm of hydrochloric acid as the first acid. Further, the GaAs single crystal substrate precursor was rinsed for 3 minutes with the same ultrapure water as the ultrapure water used in the alkali cleaning step. Thus, the alkali-cleaned surface was formed into a first acid-cleaned surface.

### 5) Second Acid Cleaning Step

The first acid-cleaned surface of the GaAs single crystal substrate precursor was subjected to acid cleaning in accordance with the vertical batch method using an acid cleaning liquid including a second acid. Specifically, the first acid-cleaned surface of the GaAs single crystal substrate precursor was immersed in an aqueous hydrochloric acid solution including 0.8 mass % of hydrochloric acid as the second acid for 5 minutes. Then, the GaAs single crystal substrate precursor was rinsed for 3 minutes with the same ultrapure water as the ultrapure water used in the alkali cleaning step. Thus, the first acid-cleaned surface was formed into a second acid-cleaned surface.

### 6) Heat Treatment Step

The second acid-cleaned surface of the GaAs single crystal substrate precursor was subjected to heat treatment under an argon gas atmosphere at 130° C. for 20 minutes. Thus, the second acid-cleaned surface was formed into a main surface having a predetermined oxide film. In this way, one GaAs single crystal substrate of sample 21 was obtained. In the GaAs single crystal substrate, the diameter and thickness of the GaAs single crystal substrate precursor were maintained.

### (Sample 22)

One GaAs single crystal substrate of a sample 22 was obtained in the same manner as in sample 21 except that in the preparation step, a semi-insulating GaAs single crystal having carbon (C) atoms added therein was sliced and chamfered to prepare a GaAs single crystal substrate precursor having a diameter of 4 inches (100 mm) and a thickness of 350 μm.

### (Sample 23)

One GaAs single crystal substrate of a sample 23 was obtained in the same manner as in sample 21 except that in the preparation step, a semi-insulating GaAs single crystal having carbon (C) atoms added therein was sliced and chamfered to prepare a GaAs single crystal substrate precursor having a diameter of 6 inches (150 mm) and a thickness of 675 μm.

### (Sample 24)

One GaAs single crystal substrate of a sample 24 was obtained in the same manner as in sample 21 except that in the preparation step, a semi-insulating GaAs single crystal having carbon (C) atoms added therein was sliced and chamfered to prepare a GaAs single crystal substrate precursor having a diameter of 8 inches (200 mm) and a thickness of 675 μm.

### <Analysis on Uniformity of Main Surface of GaAs Single Crystal Substrate>

### (Samples 21 and 22)

Five test pieces cut out from each of the main surfaces of the GaAs single crystal substrates of samples 21 and 22 were analyzed in the same manner as in [Analysis on GaAs Single Crystal Substrate Using X-Ray Photoelectron Spectroscopy] in the first test. Thus, the ratio (second integrated intensity ratio) of the integrated intensity of the integrated intensity of the metal As to the sum of the integrated intensity of As⁵⁺, the integrated intensity of As³⁺, the integrated intensity of Ga—As, and the integrated intensity of the metal As in each test piece was determined. Further, the standard deviation and the average value of the second integrated intensity ratio were calculated based on the ratio, thereby determining a standard deviation/average value.

Each of the five test pieces includes a first measurement point P1, a second measurement point P2, a third measurement point P3, a fourth measurement point P4, and a fifth measurement point P5 shown in FIG. 4. Further, each of the five test pieces was placed in a high-resolution XPS analyzer so as to apply X-ray to each of first measurement point P1, second measurement point P2, third measurement point P3, fourth measurement point P4, and fifth measurement point P5. The results are shown in Tables 2 and 3. Table 2 shows the second integrated intensity ratio in the GaAs single crystal substrate of sample 21 and the standard deviation and average value thereof. Table 3 shows the second integrated intensity ratio in the GaAs single crystal substrate of sample 22 and the standard deviation and average value thereof. As the value of the standard deviation/the average value as shown in each of Tables 2 and 3 is smaller, the property of the GaAs single crystal substrate is more uniform in the plane of the main surface.

### (Samples 23 and 24)

Nine test pieces cut out from each of the main surfaces of the GaAs single crystal substrates of samples 23 and 24 were analyzed in the same manner as in [Analysis on GaAs Single Crystal Substrate Using X-Ray Photoelectron Spectroscopy] in the first test. Thus, the ratio (third integrated intensity ratio) of the integrated intensity of the integrated intensity of the metal As to the sum of the integrated intensity of the As⁵⁺, the integrated intensity of the As³⁺, the integrated intensity of the Ga—As, and the integrated intensity of the metal As in each test piece was determined. Further, the standard deviation and the average value of the third integrated intensity ratio were calculated based on the ratio, thereby determining a standard deviation/average value.

Each of the nine test pieces includes a first measurement point P1, a second measurement point P2, a third measurement point P3, a fourth measurement point P4, a fifth measurement point P5, a sixth measurement point P6, a seventh measurement point P7, an eighth measurement point P8, and a ninth measurement point P9 shown in FIG. 5. Further, each of the nine test pieces was placed in a high-resolution XPS analyzer so as to apply X-ray to each of first measurement point P1, second measurement point P2, third measurement point P3, fourth measurement point P4, fifth measurement point P5, sixth measurement point P6, seventh measurement point P7, eighth measurement point P8, and ninth measurement point P9. The results are shown in Tables 4 and 5. Table 4 shows the third integrated intensity ratio in the GaAs single crystal substrate of sample 23 and the standard deviation and average value thereof. Table 5 shows the third integrated intensity ratio in the GaAs single crystal substrate of sample 24 and the standard deviation and average value thereof. As the value of the standard deviation/the average value as shown in each of Tables 4 and 5 is smaller, the property of the GaAs single crystal substrate is more uniform in the plane of the main surface.

TABLE 2

| | | Second Integrated Intensity Ratio | | | | | |
|---|---|---|---|---|---|---|---|
| | | 150 eV | | | 600 eV | | |
| Measurement | Coordinates | 30° | 45° | 85° | 30° | 45° | 85° |
| Point | (X, Y) | (RS1) | (RS2) | (RS3) | (RS4) | (RS5) | (RS6) |
| P1 | (0, 0) | 0.31 | 0.34 | 0.40 | 0.20 | 0.17 | 0.15 |
| P2 | (19.125, 0) | 0.29 | 0.35 | 0.39 | 0.25 | 0.18 | 0.16 |
| P3 | (0, 19.125) | 0.29 | 0.32 | 0.38 | 0.19 | 0.17 | 0.16 |
| P4 | (−19.125, 0) | 0.30 | 0.35 | 0.40 | 0.23 | 0.20 | 0.15 |
| P5 | (0, −9.125) | 0.29 | 0.31 | 0.38 | 0.23 | 0.17 | 0.16 |

| | | | | | | |
|---|---|---|---|---|---|---|
| Average | 0.30 | 0.33 | 0.39 | 0.22 | 0.18 | 0.16 |
| Standard Deviation σ | 0.009 | 0.018 | 0.010 | 0.024 | 0.013 | 0.005 |
| σ/Average | 0.030 | 0.054 | 0.026 | 0.111 | 0.073 | 0.035 |

TABLE 3

| | | Second Integrated Intensity Ratio | | | | | |
|---|---|---|---|---|---|---|---|
| | | 150 eV | | | 600 eV | | |
| Measurement | Coordinates | 30° | 45° | 85° | 30° | 45° | 85° |
| Point | (X, Y) | (RS1) | (RS2) | (RS3) | (RS4) | (RS5) | (RS6) |
| P1 | (0, 0) | 0.29 | 0.35 | 0.38 | 0.25 | 0.18 | 0.13 |
| P2 | (25, 0) | 0.27 | 0.32 | 0.4 | 0.3 | 0.21 | 0.14 |
| P3 | (0, 25) | 0.31 | 0.38 | 0.37 | 0.26 | 0.16 | 0.12 |
| P4 | (25, 0) | 0.28 | 0.3 | 0.35 | 0.28 | 0.21 | 0.14 |
| P5 | (0, 25) | 0.3 | 0.36 | 0.38 | 0.24 | 0.2 | 0.11 |

| | | | | | | |
|---|---|---|---|---|---|---|
| Average | 0.29 | 0.34 | 0.38 | 0.27 | 0.19 | 0.13 |
| Standard Deviation σ | 0.016 | 0.032 | 0.018 | 0.024 | 0.022 | 0.013 |
| σ/Average | 0.055 | 0.093 | 0.048 | 0.091 | 0.113 | 0.102 |

TABLE 4

| | | Third Integrated Intensity Ratio | | | | | |
|---|---|---|---|---|---|---|---|
| | | 150 eV | | | 600 eV | | |
| Measurement | Coordinates | 30° | 45° | 85° | 30° | 45° | 85° |
| Point | (X, Y) | (RT1) | (RT2) | (RT3) | (RT4) | (RT5) | (RT6) |
| P1 | (0, 0) | 0.33 | 0.32 | 0.37 | 0.27 | 0.18 | 0.17 |
| P2 | (37.5, 0) | 0.31 | 0.32 | 0.40 | 0.23 | 0.19 | 0.18 |
| P3 | (0, 37.5) | 0.32 | 0.34 | 0.40 | 0.24 | 0.20 | 0.19 |
| P4 | (−37.5, 0) | 0.30 | 0.35 | 0.37 | 0.21 | 0.19 | 0.19 |
| P5 | (0, −37.5) | 0.32 | 0.36 | 0.36 | 0.20 | 0.17 | 0.17 |
| P6 | (65, 0) | 0.28 | 0.30 | 0.38 | 0.25 | 0.17 | 0.15 |
| P7 | (0, 65) | 0.29 | 0.31 | 0.28 | 0.24 | 0.15 | 0.16 |
| P8 | (−65, 0) | 0.27 | 0.31 | 0.39 | 0.23 | 0.19 | 0.19 |
| P9 | (0, −65) | 0.28 | 0.32 | 0.36 | 0.27 | 0.16 | 0.16 |

| | | | | | | |
|---|---|---|---|---|---|---|
| Average | 0.30 | 0.33 | 0.37 | 0.24 | 0.18 | 0.17 |
| Standard Deviation σ | 0.021 | 0.020 | 0.036 | 0.024 | 0.016 | 0.015 |
| σ/Average | 0.071 | 0.062 | 0.099 | 0.100 | 0.092 | 0.087 |

TABLE 5

| | | Third Integrated Intensity Ratio | | | | | |
|---|---|---|---|---|---|---|---|
| | | 150 eV | | | 600 eV | | |
| Measurement | Coordinates | 30° | 45° | 85° | 30° | 45° | 85° |
| Point | (X, Y) | (RT1) | (RT2) | (RT3) | (RT4) | (RT5) | (RT6) |
| P1 | (0, 0) | 0.31 | 0.35 | 0.37 | 0.21 | 0.19 | 0.18 |
| P2 | (50, 0) | 0.30 | 0.32 | 0.37 | 0.23 | 0.18 | 0.16 |
| P3 | (0, 50) | 0.31 | 0.33 | 0.36 | 0.21 | 0.18 | 0.17 |
| P4 | (−50, 0) | 0.30 | 0.31 | 0.37 | 0.23 | 0.20 | 0.14 |
| P5 | (0, −50) | 0.28 | 0.35 | 0.34 | 0.18 | 0.17 | 0.15 |
| P6 | (90, 0) | 0.32 | 0.33 | 0.39 | 0.24 | 0.21 | 0.15 |
| P7 | (0, 90) | 0.30 | 0.34 | 0.36 | 0.21 | 0.20 | 0.19 |
| P8 | (−90, 0) | 0.32 | 0.34 | 0.38 | 0.22 | 0.20 | 0.18 |
| P9 | (0, −90) | 0.33 | 0.35 | 0.36 | 0.18 | 0.17 | 0.15 |

| | | | | | | |
|---|---|---|---|---|---|---|
| Average | 0.31 | 0.34 | 0.37 | 0.21 | 0.19 | 0.16 |
| Standard Deviation σ | 0.015 | 0.014 | 0.014 | 0.021 | 0.015 | 0.017 |
| σ/Average | 0.048 | 0.042 | 0.039 | 0.099 | 0.077 | 0.106 |

### <Review>

According to Tables 2 and 3, in the GaAs single crystal substrate of each of samples 21 and 22, the standard deviation and the average value of the second integrated intensity ratio obtained by performing the XPS under condition 1 (X-ray incident energy of 150 eV and photoelectron take-off angle of 30°) satisfy a relation in which the standard deviation/average value≤0.1. The standard deviation and the average value of the second integrated intensity ratio obtained by performing the XPS under condition 2 (X-ray incident energy of 150 eV and photoelectron take-off angle of 45°) satisfy the relation in which the standard deviation/average value≤0.1. The standard deviation and the average value of the second integrated intensity ratio obtained by performing the XPS under condition 3 (X-ray incident energy of 150 eV and photoelectron take-off angle of 85°) satisfy the relation in which the standard deviation/average value≤0.1. The standard deviation and the average value of the second integrated intensity ratio obtained by performing the XPS under condition 4 (X-ray incident energy of 600 eV and photoelectron take-off angle of 30°) satisfy the relation in which the standard deviation/average value≤0.2. The standard deviation and the average value of the second integrated intensity ratio obtained by performing the XPS under condition 5 (X-ray incident energy of 600 eV and photoelectron take-off angle of 45°) satisfy the relation in which the standard deviation/average value≤0.2. The standard deviation and the average value of the second integrated intensity ratio obtained by performing the XPS under condition 6 (X-ray incident energy of 600 eV and photoelectron take-off angle of 85°) satisfy the relation in which the standard deviation/average value≤0.11.

According to Tables 4 and 5, in the GaAs single crystal substrate of each of samples 23 and 24, the standard deviation and the average value of the third integrated intensity ratio obtained by performing the XPS under condition 1 (X-ray incident energy of 150 eV and photoelectron take-off angle of 30°) satisfy the relation in which the standard deviation/average value≤0.1. The standard deviation and the average value of the third integrated intensity ratio obtained by performing the XPS under condition 2 (X-ray incident energy of 150 eV and photoelectron take-off angle of 45°) satisfy the relation in which the standard deviation/average value≤0.1. The standard deviation and the average value of the third integrated intensity ratio obtained by performing the XPS under condition 3 (X-ray incident energy of 150 eV and photoelectron take-off angle of 85°) satisfy the relation in which the standard deviation/average value≤0.2. The standard deviation and the average value of the third integrated intensity ratio obtained by performing the XPS under condition 4 (X-ray incident energy of 600 eV and photoelectron take-off angle of 30°) satisfy the relation in which the standard deviation/average value≤0.2. The standard deviation and the average value of the third integrated intensity ratio obtained by performing the XPS under condition 5 (X-ray incident energy of 600 eV and photoelectron take-off angle of 45°) satisfy the relation in which the standard deviation/average value≤0.1. The standard deviation and the average value of the third integrated intensity ratio obtained by performing the XPS under condition 6 (X-ray incident energy of 600 eV and photoelectron take-off angle of 85°) satisfy the relation in which the standard deviation/average value≤0.2. That is, it is understood that the property of the GaAs single crystal substrate of each of samples 21 to 24 is sufficiently uniform in the plane of the main surface. Therefore, the GaAs single crystal substrate of each of samples 21 to 24 has a high mirror surface property in the whole of the main surface thereof, and an epitaxial film having a reduced haze value can be expected to be formed thereon.

Heretofore, the embodiments and examples of the present disclosure have been illustrated, but it has been initially expected to appropriately combine configurations of the embodiments and examples.

The embodiments and examples disclosed herein are illustrative and non-restrictive in any respect. The scope of the present invention is defined by the terms of the claims, rather than the embodiments and examples described above, and is intended to include any modifications within the scope and meaning equivalent to the terms of the claims.

### REFERENCE SIGNS LIST

1 GaAs single crystal substrate; 1m main surface; 10 X-ray generation facility; 11 X-ray source; 12, 14 slit; 13 grating; 20 vacuum container; 30 electron spectrometer; 50 notch; 100 analysis system; L As3d spectrum; L1 As⁵⁺ spectrum; L2 As³⁺ spectrum; L3 metal As spectrum; L4 Ga—As spectrum; P1 first measurement point; P2 second measurement point; P3 third measurement point; P4 fourth measurement point; P5 fifth measurement point; P6 sixth measurement point; P7 seventh measurement point; P8 eighth measurement point; P9 ninth measurement point; A1 to A9 measurement target; S100 preparation step; S200 cleaning step; S210 surface polishing step; S220 alkali cleaning step; S230 first acid cleaning step; S240 second acid cleaning step; S250 heat treatment step; S300 epitaxial film formation step.

1. A gallium arsenide single crystal substrate comprising a main surface having a circular shape, wherein
the gallium arsenide single crystal substrate has R1, R2, R3, R4, R5, and R6, each of which is a first integrated intensity ratio,
the first integrated intensity ratio is obtained by determining a spectrum of a detection intensity of a 3d electron of arsenic with respect to a binding energy of a photoelectron emitted to outside of the gallium arsenide single crystal substrate based on X-ray photoelectron spectroscopy in which X-ray is applied to a center of the main surface under each of below-described specific conditions,
the first integrated intensity ratio is a ratio of an integrated intensity of an arsenic element present as diarsenic pentoxide to a sum of the integrated intensity of the arsenic element present as the diarsenic pentoxide, an integrated intensity of an arsenic element present as diarsenic trioxide, an integrated intensity of an arsenic element present as gallium arsenide, and an integrated intensity of an arsenic element present as a metal arsenic,
the R1 is obtained by performing the X-ray photoelectron spectroscopy under a below-described condition 1,
the R2 is obtained by performing the X-ray photoelectron spectroscopy under a below-described condition 2,
the R3 is obtained by performing the X-ray photoelectron spectroscopy under a below-described condition 3,
the R4 is obtained by performing the X-ray photoelectron spectroscopy under a below-described condition 4,
the R5 is obtained by performing the X-ray photoelectron spectroscopy under a below-described condition 5,
the R6 is obtained by performing the X-ray photoelectron spectroscopy under a below-described condition 6, and
a relation in which at least one of the R2, the R3, and the R4 is the largest among the R1, the R2, the R3, the R4, the R5, and the R6 is satisfied, where the condition 1: X-ray incident energy of 150 eV and photoelectron take-off angle of 30°,
the condition 2: X-ray incident energy of 150 eV and photoelectron take-off angle of 45°,
the condition 3: X-ray incident energy of 150 eV and photoelectron take-off angle of 85°,
the condition 4: X-ray incident energy of 600 eV and photoelectron take-off angle of 30°,
the condition 5: X-ray incident energy of 600 eV and photoelectron take-off angle of 45°, and
the condition 6: X-ray incident energy of 600 eV and photoelectron take-off angle of 85°.

2. The gallium arsenide single crystal substrate according to claim 1, wherein each of the R1, the R2, the R3, the R4, the R5, and the R6 is 0.05 or more and 0.55 or less.

3. The gallium arsenide single crystal substrate according to claim 1, wherein the R6 is 0.1 or more and less than 0.2.

4. The gallium arsenide single crystal substrate according to claim 1, wherein the R1 is 0.2 or more and less than 0.35.

5. The gallium arsenide single crystal substrate according to claim 1, wherein the gallium arsenide single crystal substrate has a diameter of 75 mm or more and 205 mm or less.

6. The gallium arsenide single crystal substrate according to claim 1, wherein
the gallium arsenide single crystal substrate has a diameter of 75 mm or more and less than 150 mm,
the gallium arsenide single crystal substrate has RS1, RS2, RS3, RS4, RS5, and RS6, each of which is a second integrated intensity ratio,
the gallium arsenide single crystal substrate has a standard deviation and an average value of each of the RS1, the RS2, the RS3, the RS4, the RS5, and the RS6,
the standard deviation and the average value of each of the RS1, the RS2, the RS3, the RS4, the RS5, and the RS6 are obtained by determining a spectrum of a detection intensity of a 3d electron of the arsenic with respect to a binding energy of a photoelectron emitted to the outside of the gallium arsenide single crystal substrate based on X-ray photoelectron spectroscopy in which X-ray is applied to each of five measurement points on the main surface under a respective one of the condition 1, the condition 2, the condition 3, the condition 4, the condition 5, and the condition 6,
the standard deviation and the average value of each of the RS1, the RS2, the RS3, the RS4, the RS5, and the RS6 are a standard deviation and an average value of the ratio of the integrated intensity of the arsenic element present as the diarsenic pentoxide to the sum of the integrated intensity of the arsenic element present as the diarsenic pentoxide, the integrated intensity of the arsenic element present as the diarsenic trioxide, the integrated intensity of the arsenic element present as the gallium arsenide, and the integrated intensity of the arsenic element present as the metal arsenic,
a ratio of the standard deviation of the RS1 to the average value of the RS1 is 0.1 or less,
a ratio of the standard deviation of the RS2 to the average value of the RS2 is 0.1 or less,
a ratio of the standard deviation of the RS3 to the average value of the RS3 is 0.1 or less,
a ratio of the standard deviation of the RS4 to the average value of the RS4 is 0.2 or less,
a ratio of the standard deviation of the RS5 to the average value of the RS5 is 0.2 or less,
a ratio of the standard deviation of the RS6 to the average value of the RS6 is 0.11 or less, and
when the diameter is represented by D and two axes, which each pass through the center of the main surface, are each located on the main surface, and are orthogonal to each other, are defined as an X axis and a Y axis, coordinates (X, Y) of the five measurement points on the X axis and the Y axis are (0, 0), (D/4, 0), (0, D/4), (−D/4, 0), and (0, −D/4) respectively, and units of the D and each of the X and the Y in the coordinates (X, Y) are mm.

7. The gallium arsenide single crystal substrate according to claim 1, wherein
the gallium arsenide single crystal substrate has a diameter of 150 mm or more and 205 mm or less,
the gallium arsenide single crystal substrate has RT1, RT2, RT3, RT4, RT5, and RT6, each of which is a third integrated intensity ratio,
the gallium arsenide single crystal substrate has a standard deviation and an average value of each of the RT1, the RT2, the RT3, the RT4, the RT5, and the RT6,
the standard deviation and the average value of each of the RT1, the RT2, the RT3, the RT4, the RT5, and the RT6 are obtained by determining a spectrum of a detection intensity of a 3d electron of the arsenic with respect to a binding energy of a photoelectron emitted to the outside of the gallium arsenide single crystal substrate based on X-ray photoelectron spectroscopy in which X-ray is applied to each of nine measurement points on the main surface under a respective one of the condition 1, the condition 2, the condition 3, the condition 4, the condition 5, and the condition 6,
the standard deviation and the average value of each of the RT1, the RT2, the RT3, the RT4, the RT5, and the RT6 are a standard deviation and an average value of the ratio of the integrated intensity of the arsenic element present as the diarsenic pentoxide to the sum of the integrated intensity of the arsenic element present as the diarsenic pentoxide, the integrated intensity of the arsenic element present as the diarsenic trioxide, the integrated intensity of the arsenic element present as the gallium arsenide, and the integrated intensity of the arsenic element present as the metal arsenic,
a ratio of the standard deviation of the RT1 to the average value of the RT1 is 0.1 or less,
a ratio of the standard deviation of the RT2 to the average value of the RT2 is 0.1 or less,
a ratio of the standard deviation of the RT3 to the average value of the RT3 is 0.2 or less,
a ratio of the standard deviation of the RT4 to the average value of the RT4 is 0.2 or less,
a ratio of the standard deviation of the RT5 to the average value of the RT5 is 0.1 or less,
a ratio of the standard deviation of the RT6 to the average value of the RT6 is 0.2 or less, and
when the diameter is represented by D and two axes, which each pass through the center of the main surface, are each located on the main surface, and are orthogonal to each other, are defined as an X axis and a Y axis, coordinates (X, Y) of the nine measurement points on the X axis and the Y axis are (0, 0), (D/4, 0), (0, D/4), (−D/4, 0), (0, −D/4), (D/2-10, 0), (0, D/2-10), (−(D/2-10), 0), and (0, −(D/2-10)) respectively, and units of the D and each of the X and the Y in the coordinates (X, Y) are mm.

8. The gallium arsenide single crystal substrate according to claim 1, comprising an epitaxial film disposed on the main surface, wherein
a maximum value of haze of a surface of the epitaxial film is 350 ppm or less, and
an average value of the haze of the surface of the epitaxial film is 2.5 ppm or less.

9. A method of producing a gallium arsenide single crystal substrate having a main surface having a circular shape, the method comprising:
preparing a gallium arsenide single crystal substrate precursor having a surface having a circular shape; and obtaining the gallium arsenide single crystal substrate from the gallium arsenide single crystal substrate precursor, wherein
the obtaining includes
forming the surface of the gallium arsenide single crystal substrate precursor into a polished surface by polishing the surface,
forming the polished surface into an alkali-cleaned surface by cleaning the polished surface with an alkali cleaning liquid,
forming the alkali-cleaned surface into a first acid-cleaned surface by cleaning the alkali-cleaned surface with an acid cleaning liquid including 0.3 ppm by mass or more and 1 mass % or less of a first acid,
forming the first acid-cleaned surface into a second acid-cleaned surface by immersing the first acid-cleaned surface in more than 0.5 mass % and 1 mass % or less of a second acid for 1 minute or more, and
forming the second acid-cleaned surface into the main surface by performing heat treatment onto the second acid-cleaned surface in an inert gas atmosphere under conditions of 100° C. or more and 200° C. or less and 1 minute or more and 30 minutes or less, and
the second acid includes at least one selected from a group consisting of hydrofluoric acid, hydrochloric acid, nitric acid, and nitrous acid.

10. The method of producing the gallium arsenide single crystal substrate according to claim 9, comprising forming an epitaxial film on the main surface.

11. The gallium arsenide single crystal substrate according to claim 2, wherein
the R6 is 0.1 or more and less than 0.2,
the R1 is 0.2 or more and less than 0.35, and
the gallium arsenide single crystal substrate has a diameter of 75 mm or more and 205 mm or less.
